(19) United States
(12) Patent Application Publication
(10) Pub. No.: US 2003/0006371 A1
(43) Pub. Date: Jan. 9, 2003

(54) Charged-particle beam apparatus and method for automatically correcting astigmatism of charged-particle beam apparatus

(76) Inventors: Masahiro Watanabe, Yokohama (JP); Masayoshi Takeda, Mito (JP); Koichi Hayakawa, Hitachinaka (JP); Yasuhiro Gunji, Hitachiota (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/114,938

(22) Filed: Apr. 4, 2002

(30) Foreign Application Priority Data
Jul. 4, 2001 (JP) 2001-202904

(51) Int. Cl. H01J 37/28

(52) U.S. Cl. 250/310; 250/307

(57) ABSTRACT

In order to provide a charged-particle beam apparatus and an automatic astigmatism adjustment method that are capable of adjusting astigmatism and a focus in a short period of time and with a high degree of precision, the present invention implements fast, precise and automatic astigmatism and focus adjustment by detection of an astigmatic difference's direction and magnitude as well as a focal offset in processing to process a small number of 2-dimensional pictures obtained by varying a focus in two different scanning directions, and by transformation of the direction and magnitude into two kinds of astigmatism correction quantity to be used for correction of the astigmatism as well as transformation of the focal offset into a focus correction quantity to be used for correction of the focus.

In addition, by correcting astigmatic-difference errors, it is possible to implement automatic adjustment of astigmatism and a focus with a high degree of precision.

### BACKGROUND OF THE INVENTION

The present invention relates to a charged-particle beam apparatus for automatically adjusting astigmatism or the like in a charged-particle optical system for carrying out inspection, measurement, fabrication and the like with a high degree of precision by using a charged-particle beam, and relates to a method for automatically adjusting the astigmatism.

For example, an electron-beam microscope is used as an automatic inspection system for inspecting and/or measuring a microcircuit pattern created on a semiconductor wafer or the like. In the case of defect inspection, a detected picture, which is an electronic beam picture detected by a scanning electron-beam microscope, is compared with a reference picture used as a reference. In addition, in the case of measurement of a line width, a hole diameter and other quantities of a microcircuit pattern, the measurement is carried out in picture processing by using an electron-beam picture detected by a scanning electron-beam microscope. The measurement of such quantities of a microcircuit pattern is carried out in setting and monitoring conditions of a process to manufacture a semiconductor device.

In comparative inspection for detecting a defect of a pattern by comparing electronic pictures of patterns and in measurement of a line width or another quantity of a pattern by processing an electronic picture as described above, the quality of the electronic picture has a big effect on reliability of a result of the inspection. The quality of an electronic picture deteriorates due to deterioration in resolution or the like caused by aberration and defocus of an electron-beam optical system. The deterioration in picture quality deteriorates the inspection sensitivity and the measurement performance. In addition, the width of a pattern on a picture changes and a stable result of detection of a picture edge cannot be obtained. Thus, the sensitivity of detection of a defect and a result of measurement of a line width of a pattern as well as a result of measurement of hole diameter also become instable.

Traditionally, the focus and astigmatism of an electron-beam optical system are adjusted by adjusting a control current of an objective lens and control currents of two sets of astigmatism correction coils while visually observing an electronic picture. To be more specific, the focus is adjusted by changing a current flowing to the objective lens in order to change the convergence height of a beam.

It takes time to adjust the focus and astigmatism of an electron-beam optical system by adjusting a control current of an objective lens and control currents of two sets of astigmatism correction coils while visually observing an electronic picture as described above. In addition, if the surface of a sample is scanned by using an electron beam a number of times, it is quite within the bounds of possibility that a problem of damage inflicted on the sample is raised. Furthermore, by carrying out the adjustment manually, a result of adjustment may inevitably vary from operator to operator. Moreover, the astigmatism and the focal position normally vary with the lapse of time. Thus, in automatic inspection and measurement, it is necessary to adjust the astigmatism and the focal position periodically, causing a hindrance to automation.

In order to solve the problems described above, a variety of conventional automatic astigmatism correction methods have been proposed. In Japanese Patent Laid-open No. Hei 7-153407, for example, there has been disclosed an apparatus (referred to as prior art 1) wherein a 2-dimensional scanning operation is carried out on a sample by using a charged-particle beam to produce a secondary-electron signal from the sample; the secondary-electron signal from the sample; the secondary-electron signal is then differentiated and digital data with a large change is extracted; then, a position on the sample, at which the large change of the extracted data occurs, is found; subsequently, a charged-particle beam is used for scanning in the X direction only and in the Y direction only while excitement flowing to an objective lens is being changed with the found position taken as a center; a maximum value of digital data of a secondary-electron signal generated by these scanning operations is then used for detecting focal information in the X direction and focal information in the Y direction; from the focal information in the X direction and the focal information in the Y direction, a current to be flown to the objective lens is then determined and output to the objective lens; afterward, a current flowing to an astigmatism correction coil is changed and a charged-particle beam is then used for carrying out a scanning operation in the X or Y direction to produce a secondary-electron signal; and a maximum value of digital data of the secondary-electron signal is used for determining the magnitude of a current to be flown to the astigmatism correction coil in order to adjust the astigmatism and the focus of the charged-particle beam.

In addition, in Japanese Patent Laid-open No. Hei 9-161706, there has been disclosed a method (referred to as prior art 2) whereby a focus is changed back and forth by carrying out a scanning operation using an electron beam in a variety of directions in order to recognize the direction of astigmatism; then, two different astigmatism correction quantities are changed while the relation between these astigmatism correction quantities is being maintained so that the astigmatism changes only in this direction; and finally, a condition for the image to become bright is searched for. Thus, the adjustment can be carried out by limiting conditions of an astigmatism correction quantity with two degrees of freedom to a condition of an astigmatism correction quantity with one degree of freedom.

Furthermore, in Japanese Patent Laid-open No. Hei 10-106469, there has been disclosed a method (referred to as prior art 3) whereby, first of all, a focus is adjusted automatically to a position slightly shifted from an in-focus state; then, the direction of astigmatism is found by adoption of FFT of a 2-dimensional picture; subsequently, two different astigmatism correction quantities are changed while the relation between these astigmatism correction quantities is being maintained so that the astigmatism changes only in this direction; and finally, a condition for the image to become bright is searched for.

Moreover, in Japanese Patent Laid-open No. Hei 9-82257, there has been disclosed a method (referred to as prior art 4) whereby, by adopting Fourier transformation of a 2-dimensional SEM image, a point at which a change of the magnitude of the Fourier transformation is inverted is first of all found while a focus is being changed in order to determine an in-focus position; then, a 2-dimensional particle image at a focal point before the in-focus position and a 2-dimensional particle image at a focal point after the in-focus position are found; subsequently, the direction of astigmatism is found from a distribution of magnitudes of the Fourier transform; and finally, the astigmatism is corrected so that the astigmatism changes in this direction.

In addition, in U.S. Pat. No. 6,025,600, there has been disclosed a method (referred to as prior art 5) whereby, 4-direction sharpness values of an acquired SEM picture are found by increasing a focal position; then, the focal position is increased till maximums of these values are obtained; finally, a correction quantity of astigmatism is found from the maximums of the sharpness values in the 4-direction.

Furthermore, in Japanese Patent Laid-open No. Sho 59-18555 and U.S. Pat. No. 4,554,452, which is a U.S. patent of Japanese Patent Laid-open No. Sho 59-18555, there has been disclosed a method (referred to as prior art 6) whereby, an SEM picture is scanned in a variety of directions by increasing a focal position in order to find the sharpness in each of the directions; and the correction quantity of astigmatism is found from a maximum value of the sharpness found in each of the directions.

Prior art 1 adopts a method whereby, while three kinds of control quantity, namely, two kinds of astigmatism correction quantity and a focal correction quantity, are each being changed one by one, a point providing a maximum sharpness value of a secondary particle image is found by a trial-and-error technique. Thus, it takes too a long time to complete the correction of astigmatism. As a result, since the sample is exposed to a charged-particle beam for a long time, the sample may also be damaged by charge-up, contamination and the like. In addition, if astigmatism is adjusted automatically or visually by taking sharpness as a reference, a state in which the astigmatism is not correctly eliminated easily results in dependence on the sample pattern.

Also in the case of prior art 2, after examining the direction of astigmatism by changing the focal point back and forth, it is necessary to carry out a 1-dimensional scanning operation by changing the focal point back and forth while changing the astigmatism adjustment quantity in order to repeatedly carry out an operation to search for a condition in which in-focus positions in two directions coincide with each other, so that prior art 2 has a problem that it takes too much time. In addition, there is also raised a problem that a post-radiation mark is left on the sample due to the fact that the scanning operation using an electron beam is a one-dimensional operation. Moreover, there is also raised a problem that stable astigmatism correction cannot be carried out since a sufficient signal cannot be obtained in dependence on the location of the one-dimensional scanning operation if the sample does not have uniform texture thereon.

Also in the case of prior art 3, since the adjustment comprises two steps, namely, the step of changing the focus back and forth and the step of changing the astigmatism correction quantity up and down, there are raised problems that it takes time to carry out the adjustment and, in addition, the damage inflicted on the sample is great. Furthermore, in order to find the direction of the astigmatism by adoption of the FFT, the method requires a precondition that the spectrum of a picture with no astigmatism generated is uniform. Thus, there is raised a problem that the number of usable samples is inevitably limited.

As described above, either prior art 1, 2 or 3 includes neither a method of finding the direction and the magnitude of astigmatism in a stable manner from a particle picture nor computation of a correction quantity to be supplied to an astigmatism adjustment means from the direction and the magnitude of the astigmatism. Thus, the astigmatism correction quantity must be changed and a result must be checked repeatedly on a trial-and-error basis so that it takes time to carry out the adjustment and, at the same time, the sample is contaminated whereas damage caused by charge-up is inflicted upon the sample. In addition, in the case of a one-dimensional beam scanning operation, there is raised a problem of precision deterioration for scanning of a location with a coarse pattern on the sample.

Moreover, in the case of prior art 4, the direction and the strength of astigmatism are found from Fourier transformation of a 2-dimensional picture with the focus changed back and forth. However, prior art 4, does not include a concrete method of computing a correction quantity to be supplied to an astigmatism adjustment means from the direction and the strength of the astigmatism. Furthermore, the meaning of the strength seen from the physics point of view is not defined clearly. Thus, there is raised a problem that the correction quantity to be supplied to the astigmatism adjustment means cannot be found with a sufficient degree of accuracy.

In addition, in the case of prior art 5, an astigmatism correction quantity can be found from an SEM picture with a sequence of focal points shifted, and the amount of damage inflicted on the sample can be reduced. However, this method does not consider the case of a sharpness curve becoming unsymmetrical or having two peaks for large astigmatism. Furthermore, when degrees of directional sharpness are to be found from a picture, the sharpness in the vertical direction and the sharpness in the horizontal direction include many noises in comparison with the sharpness in the slanting direction due to beam noises and response characteristics of a detector. As a result, there is raised a problem of an instable operation for a dark sample.

In the case of prior art 6, a scanning axis is rotated in more than three directions to obtain a signal and sharpness in each of the directions is found from this cross-sectional signal so that it takes time to carry out the scanning operation. To put it concretely, there is raised a problem that the found sharpness is prone to an error because of an effect of edges in other directions due to the fact that the processing is a one-dimensional differentiation process.

As a problem common to prior arts 5 and 6, the astigmatism correction quantity cannot be found with a high degree of accuracy or it takes time to converge the astigmatism correction if the edge of a sample pattern is one-sided in a certain direction so that the sharpness in this certain direction is affected by an edge in another direction and inevitably increases. This phenomenon is caused by the fact that the astigmatism correction quantity is found by adopting linear junction of maximum values of the sharpness.

### SUMMARY OF THE INVENTION

It is thus an object of the present invention addressing the problems described above to provide a charged-particle beam apparatus and an automatic astigmatism adjustment method, which are capable of automatically correcting astigmatism and a focus in a short period of time while reducing the amount of damage inflicted upon samples to the minimum by finding two or more astigmatism correction quantities and a focus correction quantity as a set from a small number of 2-dimensional pictures for a variety of samples.

Furthermore, it is another object of the present invention to provide a charged-particle beam apparatus and an automatic astigmatism adjustment method, which are capable of automatically correcting astigmatism in a short period of time while reducing the amount of damage inflicted upon samples to the minimum by finding two or more astigmatism correction quantities and a focus correction quantity at the same time from a small number of 2-dimensional pictures for a variety of samples.

In addition, it is a further object of the present invention to provide a charged-particle beam apparatus and an automatic astigmatism adjustment method, which are capable of carrying out inspections, measurements, fabrications or the like in a stable manner over a long period of time and with a high degree of reliability by improving the quality of a particle picture obtained from an object substrate through automatic correction of astigmatism and a focus in a charged-particle optical system.

Moreover, it is a still further object of the present invention to provide a sample for use in astigmatism and focus adjustment of a charged-particle beam proper for automatically correcting astigmatism and a focus in a short period of time while reducing the amount of damage inflicted upon samples to the minimum in a charged-particle optical system.

In addition, it is a still further object of the present invention to provide an automatic astigmatism adjustment method capable of automatically correcting astigmatism and a focus in a short period of time from a 2-dimensional particle picture, and provide a sample for the method.

That is to say, a charged-particle beam apparatus according to the present invention comprises:

a stage on which a sample is set;

a charged-particle optical system for converging a charged-particle beam generated by a charged-particle source;

a scanning means for scanning the sample by radiating the charged-particle beam converged by the charged-particle optical system to the sample;

a focus control means for controlling a focal position of the charged-particle beam converged by the charged-particle optical system;

an astigmatism adjustment means for adjusting astigmatism of the charged-particle beam converged by the charged-particle optical system;

a particle-picture detection means for detecting particle pictures, which are generated by the sample scanned by the scanning means by radiating the converged charged-particle beam to the sample and each have a plurality of focal positions, and for obtaining two sets of 2-dimensional particle pictures each having a plurality of focal positions by changing a scanning direction;

a picture-processing means for computing an astigmatic difference of the converged charged-particle beam on the basis of the 2-dimensional particle picture which has a plurality of focal positions and is obtained by the particle-picture detection means where the computed astigmatic difference is defined as the astigmatic difference's magnitude d and direction a or a vector (dx, dy) representing the astigmatic difference; and

a control system for adjusting and controlling the astigmatism of the converged charged-particle beam by feeding back an astigmatism correction quantity based on the converged charged-particle beam's astigmatic difference computed by the picture-processing means to the astigmatism adjustment means.

In addition, an automatic astigmatism adjustment method according to the present invention is characterized in that the method comprises:

a first process including the steps of:

converging a charged-particle beam, which is generated by a charged-particle source, by using a charged-particle optical system;

radiating the converged charged-particle beam to a sample, on which a pattern including edge elements in at least three directions has been created, by using a scanning means for scanning the sample; and

obtaining a 2-dimensional particle picture by detection of a particle picture, which is generated from the sample, by using a charged-picture detection means,

a second process of computing the converged charged-particle beam's astigmatic difference and focal offset by using a picture-processing means on the basis of the 2-dimensional particle picture obtained in the first process; and

a third process including the steps of:

controlling and adjusting the astigmatism of the converged charged-particle beam by feeding back an astigmatism correction quantity based on the converged charged-particle beam's astigmatic difference computed by the picture-processing means in the second process to an astigmatism adjustment means; and

controlling and adjusting a focus of the converged charged-particle beam by feeding back a focus correction quantity based on the converged charged-particle beam's focal offset computed by the picture-processing means in the second process to a focus control means.

Furthermore, the present invention also provides a sample for adjustment of astigmatism of a charged-particle beam. The sample is characterized in that at least three areas each having a one-directional pattern are provided within a visual field of a charged-particle optical system.

As described above, in accordance with the present invention, picture processing is carried out on a small number of 2-dimensional particle pictures obtained by changing a focus in order to compute astigmatic difference and a focal offset z. The astigmatic difference is defined as an interval between focal positions for a pattern in the orthogonal direction. The astigmatic difference is typically represented by a magnitude δ and a direction α or a vector. With astigmatism generated, when the focus is changed from an in-focus state, the picture gets blurred non-uniformly. At a point of time the elliptical shape of the beam becomes thinnest, a pattern parallel to the long axis of the ellipse becomes bright. On the other hand, the degree of blurring of a pattern perpendicular to the long axis of the ellipse increases. In order to compute the degree of blurring seen from a particle-picture point of view, in the present invention, degrees of directional sharpness {d0(f), d45(f), d90(f), d135(f)} are defined. Variations in the directional sharpness are analyzed while the focus is being moved back and forth in order to find the astigmatic difference, which is typically represented by a magnitude δ and a direction α or a vector, and the focal offset z. In this case, the degrees of directional sharpness in the 45-degree and 135-degree directions are noise-proof and accurate even for a faint pattern. Thus, two sets of states are possible. The two sets of states are either a state with the scanning direction set in a reference direction and the 45-degree or 135-degree direction or a state with the scanning direction set in the reference direction and the −45-degree or −135-degree direction. Then, the degrees of sharpness in the 45-degree and 135-degree directions are computed for each of the picture states. As a result, a set of four degrees of sharpness {d0(f), d45(f), d90(f), d135(f)} is obtained. The four degrees of sharpness {d0(f), d45(f), d90(f), d135(f)} are further split to a set of two types of astigmatism correction quantity and a focus correction quantity in order to implement adjustment of the astigmatism and the focus.

With this configuration, astigmatism correction quantities and a focus correction quantity are computed as a set from a small number of 2-dimensional particle pictures obtained by varying the focus. Thus, the astigmatism and the focus can be adjusted in a short period of time and with only a small amount of damage inflicted on the sample. In addition, while the focal distance is being changed, degrees of directional sharpness of pictures taken for the same sample are compared with each other to find values of the astigmatic difference. Thus, the adjustment of the astigmatism and the focus can be implemented with a high degree of precision independently of a pattern on the sample. The only condition regarding the pattern on the sample is that the pattern shall include an edge element in each direction even if the magnitude of each edge element is small. In this case, what is called the edge element is not limited to a clear pattern boundary but can also be a small injury, an infinitesimal pattern, a corner's pattern having a shape resembling a small circular arc or the like.

In addition, in the present invention, when a maximum value of sharpness is used in an analysis of directional sharpness, there is raised a problem that the error of the astigmatism correction quantity increases. In order to solve this problem, the center of gravity of a curve representing the sharpness is found. In the case of an asymmetrical sharpness curve or a double-peak sharpness curve, the center of gravity exhibits an effect to correct the position of the center of the sharpness curve in a direction toward a portion with a larger base in the area enclosed by the curve or a portion with a primary peak. Thus, the astigmatism can always be corrected with a high degree of accuracy. Due to an effect of aberration other than the astigmatism of the charged-particle optical system, however, the astigmatism correction quantity generally includes an error. Thus, if necessary, in the case of large astigmatism, the astigmatism is corrected a plurality of times till a change in astigmatism correction quantity becomes small enough or is converged to a sufficiently small value. As a result, the correction of the astigmatism can be prevented from ending in a failure.

Furthermore, the present invention also provides a method of using linear correction processing as well as non-linear correction processing using in-focus positions p0, p45, p90 and p135 for degrees of directional sharpness to find an astigmatism correction quantity. In accordance with this method, also in the case of a one-sided direction of a pattern on the sample, a shift of the sharpness-curve shape in a direction toward an adjacent area due to an effect of the pattern in a direction of increasing strength caused by the one-sided direction is corrected in the calculation of the astigmatism correction quantity. As a result, the astigmatism can be corrected in a stable manner and within a short period of time.

The present and other objects, features and advantages of the present invention as well as the manner of realizing them will become more apparent, whereas the invention itself will be best understood from a study of the following description of some preferred embodiments of the invention as illustrated in the following accompanying drawings.

### BRIEF DESCRIPTION OF THE DRAWINGS

FIG. 1 is a block diagram showing the configuration of an inspection/measurement apparatus, which is an embodiment implementing a charged-particle beam apparatus provided by the present invention, in a simple and plain manner;

FIG. 2 is a top view of astigmatism correction coils;

FIG. 3 is a diagram showing a relation between astigmatism and beam-spot shapes;

FIG. 4 includes top views of a pattern for focus and astigmatism correction according to embodiments;

FIG. 5 is a flowchart representing picture processing carried out by a picture-processing circuit employed in the charged-particle beam apparatus shown in FIG. 1 to compute astigmatism and focus correction quantities;

FIG. 6 is diagrams showing curves representing relations among a computed directional sharpness value dθ(f), the astigmatic difference's magnitude δ and direction α and a focal offset z;

FIG. 7 includes diagrams each showing typical picture processing to find directional sharpness;

FIG. 8 includes top views each showing the shape of a sample serving as a calibration target for fast focus and astigmatism correction;

FIG. 9 is a flowchart representing processing carried out by the picture-processing circuit employed in the charged-particle beam apparatus shown in FIG. 1 to compute astigmatism and focus correction quantities in the case of the calibration target shown in FIG. 8;

FIG. 10 is a top view of a wafer and a visual-field moving sequence in periodical calibration for focus and astigmatism drifts;

FIG. 11 is a graph representing a relation between the focus value and the sharpness and serving as a means for explaining a method of interpolating the position of a peak of a directional-sharpness curve;

FIG. 12A includes cross-sectional diagrams each showing the shape of a beam at a variety of locations in the z direction;

FIGS. 12B and 12C include graphs each representing a relation between the focus value and the sharpness and serving as a means for explaining a case of a double-peak curve of directional sharpness;

FIG. 13 is a graph representing a relation between the focus value and the sharpness and serving as a means for explaining a method of using the center of gravity of a directional-sharp curve as a central position of the curve;

FIG. 14 is a graph representing a relation between the focus value and the sharpness and serving as a means for explaining a method of finding a central position of a directional-sharp curve by computing a weighted average of maximum-value positions;

FIGS. 15A and 15B are graphs representing a relation between the focus value and the sharpness and serving as a means for explaining a method of finding a central position of a directional-sharp curve by adopting a symmetry-matching technique;

FIG. 16 is a graph representing a relation between the focus value and the sharpness and serving as a means for explaining differences in characteristic, which are caused by the direction of a directional-sharpness curve;

FIG. 17 includes diagrams, which each show a top view of a wafer and a graph representing a relation between the focus value and the sharpness and each serve as a means for explaining a method of finding degrees of directional sharpness in four directions with a higher degree of accuracy from two pictures obtained as results of scanning operations in two directions;

FIG. 18 is a flowchart representing processing to correct astigmatism for a case in which the directional sharpness is computed by adopting the method shown in FIG. 17;

FIG. 19 is diagrams, which each show a top view of a wafer and a graph representing a relation between the focus value and the sharpness and each serve as a means for explaining a case in which the directional sharpness is shifted by an effect of a pattern existing in another direction; and

FIG. 20 is a graph representing a relation between the focus value and the sharpness and serving as a means for explaining a principle underlying more precise correction of astigmatism by correcting the phenomenon shown in FIG. 19.

### DESCRIPTION OF THE PREFERRED EMBODIMENTS

A description will be made of a charged-particle beam apparatus, an automatic astigmatism correction method and a sample used in adjustment of astigmatism of a charged-particle beam according to preferred embodiments of the present invention with reference to the drawings.

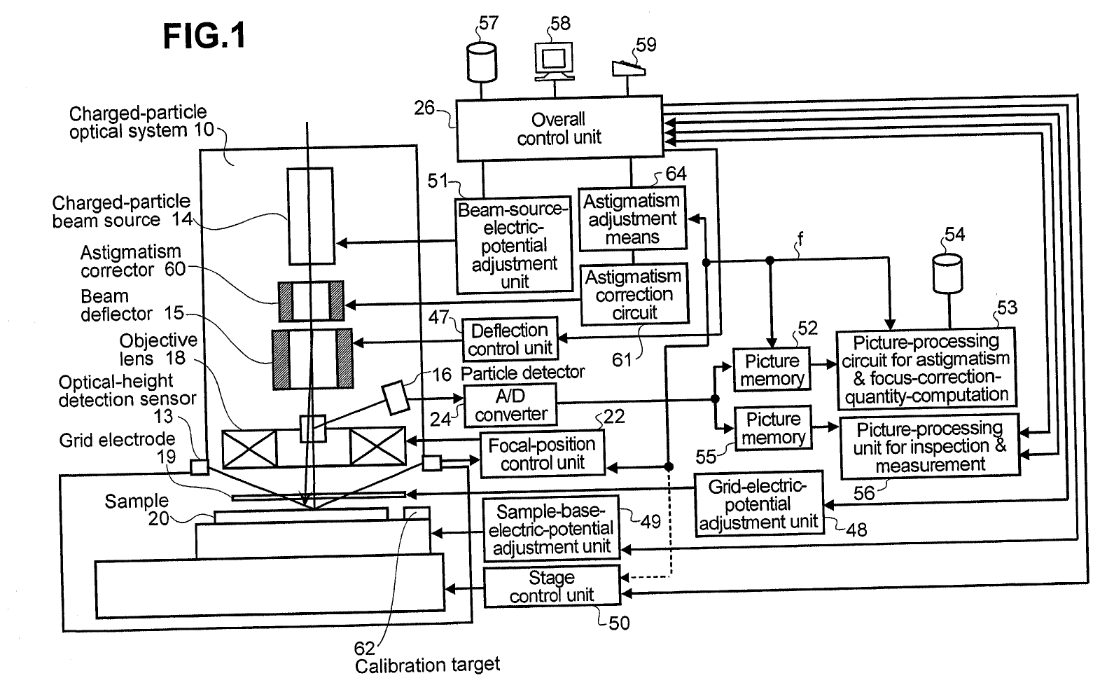

As shown in FIG. 1, the inspection/measurement apparatus, which is an embodiment implementing a charged-particle beam apparatus provided by the present invention, comprises a charged-particle optical system 10, a control system and a picture-processing system. The control system controls a variety of components composing the charged-particle optical system 10. On the other hand, the picture-processing system carries out processing on a picture based on secondary particles or reflected particles. The secondary particles or the reflected particles are detected by a particle detector 16 employed in the charged-particle optical system 10.

The charged-particle optical system 10 comprises a charged-particle beam source 14, an astigmatism corrector 60, a beam deflector 15, an objective lens 18, a sample base 21, an XY stage 46, a grid electrode 19, a retarding electrode not shown in the figure, an optical-height detection sensor 13 and the particle detector 16. The charged-particle beam source 14 emits a charged-particle beam such as an electron beam and an ion beam. By application of an electric field, the astigmatism corrector 60 corrects astigmatism of the charged-particle beam emitted by the charged-particle beam source 14. The beam deflector 15 carries out a scanning operation by deflecting the charged-particle beam emitted by the charged-particle beam source 14. By using a magnetic field, the objective lens 18 converges the charged-particle beam deflected by the beam deflector 15. On the sample base 21, a sample 20 is mounted. A target 62 for calibration use is fixed at a location on the sample base 21 beside the sample 20. The XY stage 46 moves the sample base 21. The grid electrode 19 has an electric potential close to the ground. Provided on the sample base 21, the retarding electrode has a negative electric potential if the charged-particle beam radiated to the sample 20 and the calibration target 62, which are provided on the sample base 21, is an electron beam, but has a positive electric potential if the charged-particle beam is an ion beam. The optical height detection sensor 13 measures the height of the sample 20 or the like by adopting typically an optical technique. The particle detector 16 detects secondary particles emitted from the surface of the sample 20 as a result of radiation of the charged-particle beam to the sample 20. The particle detector 16 may also detect particles reflected by typically a reflecting plate. It should be noted that the astigmatism corrector 60 can be an astigmatism correction coil based on a magnetic field or an astigmatism correction electrode based on an electric field. In addition, the objective lens 18 can be an objective coil based on a magnetic field or an electrostatic objective lens based on an electric field. Furthermore, the objective lens 18 may be provided with a coil 18a for focus correction. In this way, the astigmatism corrector 60, an astigmatism correction circuit 61 and other components constitute an astigmatism adjustment means.

A stage control unit 50 controllably drives the movement (the travel) of the XY stage 46 while detecting the position (or the displacement) of the XY stage 46 in accordance with a control command issued by an overall control unit 26. It should be noted that the XY stage 46 has a position-monitoring meter for monitoring the position (or the displacement) of the XY stage 46. The monitored position (or the displacement) of the XY stage 46 can be supplied to the overall control unit 26 by way of the stage control unit 50.

A focal-position control unit 22 controllably drives the objective lens 18 in accordance with a command issued by the overall control unit 26 and on the basis of the sample surface's height measured by the optical height detection sensor 13 so as to adjust the focus of the charged-particle beam to a position on the sample 20. It should be noted that by adding a Z-axis component to the XY stage 46, the focus can be adjusted by controllably driving the Z-axis component instead of the objective lens 18. In this way, a focus control means can be configured to include the objective lens 18 or the Z-axis component and the focal-position control unit 22.

A deflection control unit 47 supplies a deflection signal to the beam deflector 15 in accordance with a control command issued by the overall control unit 26. In this case, the deflection signal may be properly corrected so as to compensate for variations in magnification, which accompany variations in surface height of the sample 20, and a picture rotation accompanying control of the objective lens 18.

In accordance with an electric-potential adjustment command issued by the overall control unit 26, a grid-electric-potential adjustment unit 48 adjusts an electric potential given to the grid electrode 19 provided at a position above and close to the sample 20. On the other hand, in accordance with an electric-potential adjustment command issued by the overall control unit 26, a sample-base-electric-potential adjustment unit 49 adjusts an electric potential given to the retarding electrode provided at a position above the sample base 21. In this way, the grid electrode 19 and the retarding electrode can be used for giving a negative or positive electric potential to the sample 20 in order to reduce the velocity of respectively an electron beam or an ion beam traveling between the objective lens 18 and the sample 20. Thus, the resolution in a low-acceleration-voltage area can be improved.

In accordance with a command issued by the overall control unit 26, a beam-source-electric-potential adjustment unit 51 adjusts an electric potential given to the charged-particle beam source 14 in order to adjust an acceleration voltage of the charged-particle beam emitted by the charged-particle beam source 14 and/or adjust a beam current.

The beam-source-electric-potential adjustment unit 51, the grid-electric-potential adjustment unit 48 and the sample-base-electric-potential adjustment unit 49 are controlled by the overall control unit 26 so that a particle picture with a desired quality can be detected by the particle detector 16.

In correction of astigmatism and a focus, an astigmatism adjustment unit 64 provided by the present invention issues a control command for changing a focal position (a focus f) to the focal-position control unit 22 so that the focal-position control unit 22 controllably drives the objective lens 18. As a result, while the charged-particle beam is being radiated to an area on the sample 20 or the calibration target 62, the focus is changed. In the area, a pattern including edge elements of the same degree in all directions like one shown in FIGS. 4A or 4B is created. By doing so, the particle detector 16 detects a plurality of particle-picture signals with varied focuses f, and the particle-picture signals are each converted by an A/D converter 24 into a particle digital picture signal (or digital picture data), which is stored in a picture memory 52, being associated with a focus command value f output by the astigmatism adjustment unit 64. Then, an astigmatism & focus-correction-quantity-computation picture-processing circuit 53 reads out the a plurality of particle digital picture signals having varied focuses. The astigmatism & focus-correction-quantity-computation picture-processing unit 53 then finds degrees of directional sharpness d0(f), d45(f), d90(f) and d135(f) for the particle digital picture signals each associated with a focus command value f. Then, the astigmatism & focus-correction-quantity-computation picture-processing unit 53 finds focus values f0, f45, f90 and f135 at which the degrees of directional sharpness d0(f), d45(f), d90(f) and d135(f) respectively each reach a peak. From the focus values f0, f45, f90 and f135, the astigmatism & focus-correction-quantity-computation picture-processing unit 53 then finds an astigmatic difference and a focal offset z. The astigmatic difference can be an astigmatic-difference vector (dx, dy) or the astigmatic difference's direction α and magnitude δ. The astigmatic difference and the focal offset z are supplied to the overall control unit 26 to be stored in a storage unit 57.

The overall control unit 26 computes astigmatism correction quantities (Δstx, Δsty) for the astigmatic differences found as described above and stored in the storage unit 57 from a relation between the astigmatic difference and the astigmatism correction quantity. The relation between the astigmatic difference and the astigmatism correction quantity is found in advance as a characteristic of the astigmatism corrector 60. The overall control unit 26 also computes a focus correction quantity for the focal offset z found as described above and stored in the storage unit 57 from a relation between the focal offset z and the focus correction quantity. The relation between the focal offset z and the focus correction quantity is found in advance as a characteristic of the objective lens 18. The astigmatism correction quantities (Δstx, Δsty) and the focus correction quantity, which are found by the overall control unit 26, are supplied to the astigmatism adjustment unit 64.

The astigmatism adjustment unit 64 provides the astigmatism correction quantities (Δstx, Δsty) received from the overall control unit 26 to an astigmatism correction circuit 61 so that the astigmatism corrector 60 is capable of correcting the astigmatism of the charged-particle beam. The astigmatism corrector 60 comprises an astigmatism correction coil based on a magnetic field or an astigmatism correction electrode based on an electric field. The astigmatism adjustment unit 64 supplies the focus correction quantity to the focal-position control unit 22 so as to control a coil current flowing to the objective lens 18 or a coil current flowing to a focus correction coil 18a not shown in the figure. As a result, the focus is corrected.

As another method, a Z-axis component is provided as a portion of the XY stage 46. In this case, the astigmatism adjustment unit 64 issues a control command for moving the focus back and forth or changing the height of the sample 20 to a stage control unit 50 by way of the overall control unit 26 or directly. In accordance with this control command, the stage control unit 50 drives the Z-axis component in the direction of the Z axis in order to move the focus back and forth so that a particle picture with a focus varying is obtained from the particle detector 16. Then, the astigmatism & focus-correction-quantity-computation picture-processing unit 53 finds astigmatism correction quantities and a focus correction quantity. The focus correction quantity is fed back to the Z-axis component of the XY stage 46 while the astigmatism correction quantities are fed back to the astigmatism corrector 60. The fed-back quantities are used for correction. Of course, the component for acquiring a picture by moving the focus back and forth is different from the component for carrying out final focus correction. That is to say, one of the components may be the focal-position control unit 22 while the other component may be the Z-axis component of the XY stage 46. As an alternative, it is nice to control both the components at the same time as a combination so as to adjust the position of the sample 20 or the calibration target 62 relative to the focal position to a desired distance. It should be noted that, by controlling the objective lens 18 rather than the Z-axis component, excellent responsiveness can be obtained.

As described above, the correction of the astigmatism and the focus is based on control executed by the astigmatism adjustment unit 64 in accordance with a command issued by the overall control unit 26. The overall control unit 26 receives a particle picture with corrected astigmatism and a corrected focus, which are stored in the picture memory 52, directly or by way of the astigmatism & focus-correction-quantity-computation picture-processing unit 53, and displays the picture on a display means 58. As a result, the overall control unit 26 is capable of allowing the operator to visually examine corrected data such as the astigmatism and express acceptance or denial of the corrected data.

In addition, during an inspection and/or a measurement, for example, the XY stage 46 is controlled to bring a predetermined position on the sample 20 to the visual field of the charged-particle optical system. Then, the particle detector 16 acquires a particle-picture signal, which is converted by the A/D converter 24 into a particle digital picture signal to be stored in a picture memory 55. Subsequently, on the basis of the detection particle digital picture signal stored in the picture memory 55, an inspection & measurement picture-processing circuit 56 measures dimensions of a fine pattern created on the sample 20 and/or inspects a fine pattern generated on the sample 20 for a defect inherent in the pattern and/or for a defect caused by a foreign material. Results of the measurement and the inspection are supplied to the overall control unit 26. By correcting the astigmatism and the focus in accordance with the present invention at least periodically in this way, it is possible to implement inspection or measurement based on a particle picture with the aberration thereof always corrected.

It should be noted that, in the case of particle-picture-based inspection of a defect or the like, the inspection & measurement picture-processing unit 56 repeatedly delays a detected detection particle digital picture signal by a period of time corresponding to a pattern in order to create a reference particle digital picture signal. The inspection & measurement picture-processing unit 56 then compares the detection particle digital picture signal with the reference particle digital picture signal by making the position of the former coincide with the position of the latter in order to detect a discrepancy or a difference picture as a defect candidate. Then, the inspection & measurement picture-processing unit 56 carries out processing wherein a characteristic quantity of the defect candidate is extracted and false information to be eliminated from the characteristic quantity is identified. As a result, the sample 20 can be inspected for a true defect.

Since the effects of charge-up, dirt, damage and the like on the sample 20 are small, the optical height detection sensor 13 is capable of detecting variations in surface height of the sample 20 at inspection or measurement positions. The detected variations are fed back to the focal-position control unit 22 so that an in-focus state can always be maintained. If the optical height detection sensor 13 is used in this way, by carrying out automatic adjustment of astigmatism and a focus at another position on the sample 20 or at the calibration target 62 placed on the sample base 21 either in advance or periodically during an inspection or a measurement, the radiation of a converged charged-particle beam used for the automatic adjustment of astigmatism and a focus can be removed from the actual sample 20 or reduced substantially. As a result, the effects of charge-up, dirt, damage and the like on the sample 20 can be eliminated.

The following description explains the automatic adjustment of astigmatism and a focus in the converged charged-particle optical system provided by the present invention. In accordance with the present invention, astigmatism values and focal offsets are collected from a small number of 2-dimensional particle pictures, and converted into astigmatism and focus correction quantities, which are used in one correction.

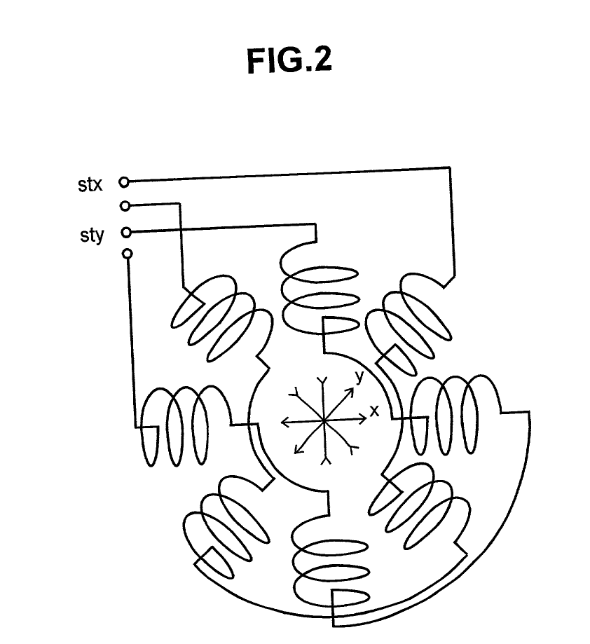

FIG. 2 is a diagram showing a configuration comprising 2 sets of astigmatism correction coils based on a magnetic field to provide an embodiment of the astigmatism corrector 60. In a configuration comprising two sets of astigmatism correction coils, a current flowing through coils composing one of the sets stx and sty shown in FIG. 2 has an effect to stretch the beam in a certain direction but shrink the beam in a direction perpendicular to the certain direction. If the sets are controlled as a combination with one of the sets shifted in the 45-degree direction from the other, the astigmatism can be adjusted by a required amount in any arbitrary direction. Of course, the astigmatism corrector 60 can also be configured to comprise electrodes based on an electric field.

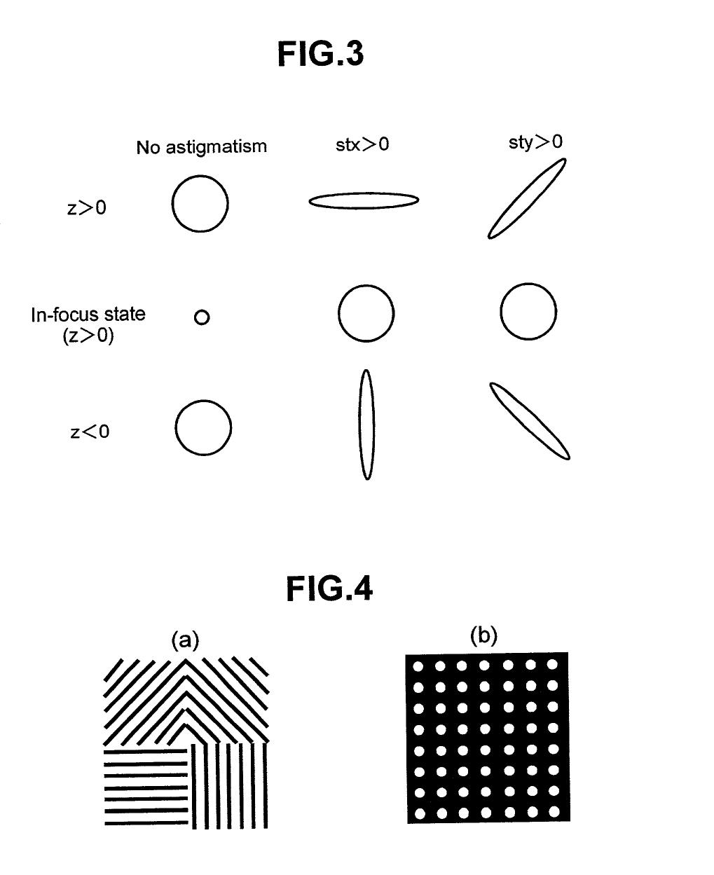

Next, the state of astigmatism is explained by referring to FIG. 3. A column on the left side is a column of shapes of a converged charged-particle beam with the astigmatism thereof corrected. The top circle is the shape of a converged charged-particle beam with a high focal position (Z>0). The middle circle is the shape of a converged charged-particle beam in an in-focus state (Z=0). The bottom circle is the shape of a converged charged-particle beam with a low focal position (Z<0). As shown in the column on the left side, a converged charged-particle beam in an in-focus state is converged to a small point and the top and bottom circles have diameters increased symmetrically with respect to the middle circle.

A column at the middle of the figure is a column of shapes of a converged charged-particle beam with a current flown through the coils of the set stx to generate astigmatism. For Z>0, the beam is stretched in the horizontal direction. For Z<0, the beam is stretched in the vertical direction. In an in-focus state, the cross section of the beam becomes circular but the diameter of the cross section is not reduced sufficiently.

A column on the right side of the figure is a column of shapes of a converged charged-particle beam with a current flown through the coils of the set sty to generate a shift from an in-focus position. The cross section of the beam becomes elliptical oriented in 45-degree directions. The direction of the long axis of elliptical cross section for Z>0 is perpendicular to the direction for Z<0.

Thus, by flowing currents to both the sets stx and sty, astigmatism of any arbitrary orientation can be deliberately generated in any arbitrary direction. As a result, pre-adjustment astigmatism of the charged-particle optical system can be canceled by the deliberately generated astigmatism to result in corrected astigmatism.

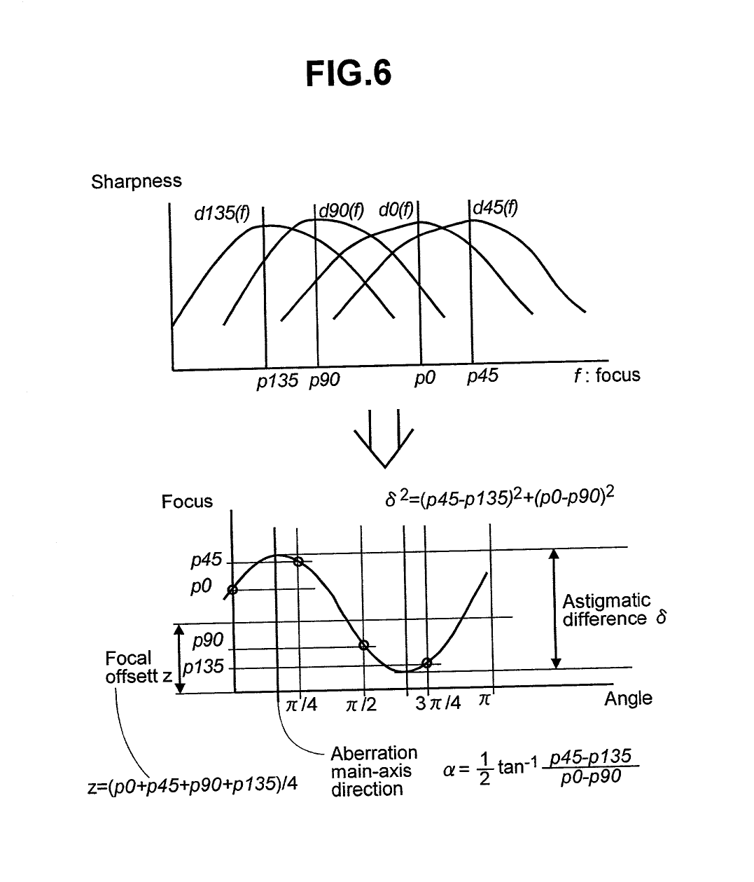

That is to say, in a state with astigmatism generated, the charged-particle beam blurs into an elliptical shape for a shift from an in-focus condition as shown in FIG. 3. At positions ±Z sandwiching the focus, the elliptical shape of the beam becomes thinnest, and the orientation of the ellipse at the position +Z is perpendicular to the orientation at the position −Z. The magnitude of the astigmatic difference is expressed by the focal distance 2Z between these two positions while the direction of the astigmatic difference is represented by the orientation of the ellipse. The focal distance 2Z between these two positions is referred to as an astigmatic difference, which is denoted by notation δ in FIG. 6. The direction of the astigmatic difference is denoted by an astigmatic difference's direction a in FIG. 6. In addition, a vector representing the astigmatic difference can also be expressed by notation (dx, dy).

Next, correction of the astigmatism and the focus is explained by referring to FIGS. 4 to 7. FIGS. 4A and 4B are diagrams each showing a top view of an embodiment of a pattern created on the sample 20 or the calibration target 62 to be used for correction of a focus and astigmatism. As a pattern for correcting astigmatism and a focus, it is nice to use a pattern including edge elements generated by the astigmatism in three or more directions to the same degree. FIG. 4A is a diagram showing a stripe pattern created over four different areas having stripe directions different from each other. FIG. 4B is a diagram showing a circle pattern having edge elements in four directions with circles being distributed two dimensionally at predetermined pitches. In the case of a pattern on a sample in particular, it is possible to use such a pattern created to include edge elements in three or more directions to the same degree. In this case, however, information on a position at which this pattern is created is entered to the overall control unit 26 in advance by using an input means 59 to be cataloged in the storage unit 57. As an alternative, it is necessary for the operator to specify a position on a proper sample used for correcting astigmatism and a focus. In addition, of course, information on a position at which the calibration target 62 is placed on the sample base 21 is entered to the overall control unit 26 in advance by using the input means 59 to be cataloged in the storage unit 57.

For the reason described above, first of all, the XY stage 46 is controllably driven on the basis of positional information of a pattern for correction of astigmatism and a focus to position the pattern at a location in close proximity to the optical axis of the charged-particle optical system. The information is supplied by the overall control unit 26 to the stage control unit 50. Then, while the charged-particle beam is being radiated to the pattern for correction of astigmatism and a focus in a scanning operation according to a command issued by the overall control unit 26 to the deflection control unit 47, the astigmatism adjustment unit 64 issues commands to the focal-position control unit 22 to have the following operations take place:

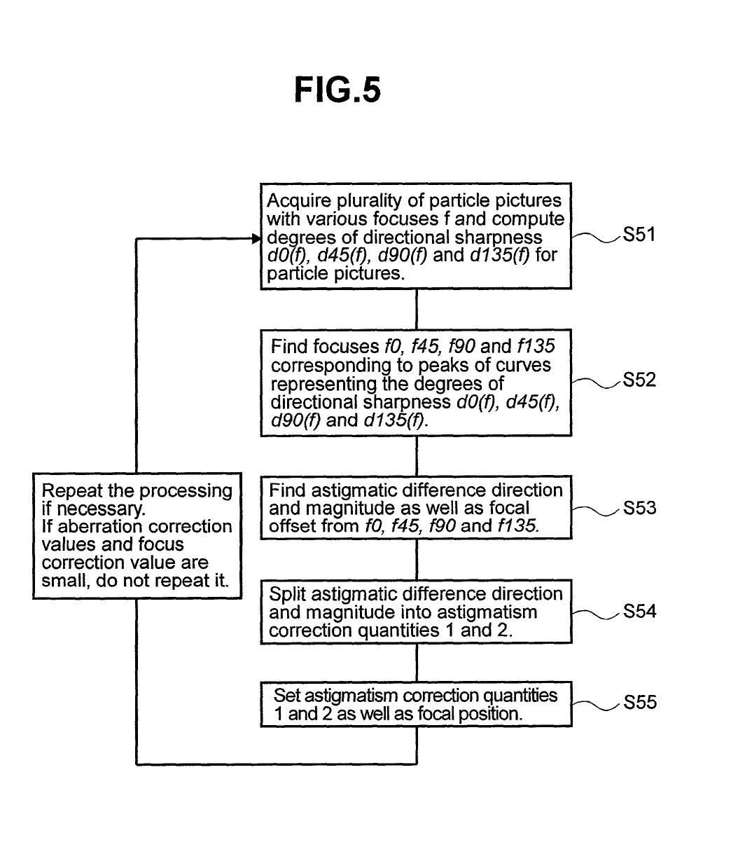

(1) At a step S51 of a flowchart shown in FIG. 5, the particle detector 16 is driven to acquire a plurality of pictures while changing the focus f as shown in FIG. 5 to be stored in the picture memory 52 and the astigmatism & focus-correction-quantity-computation picture-processing unit 53 is driven to compute degrees of directional sharpness at angles of 0, 45, 90 and 135 degrees for the pictures, producing d0(f), d45(f), d90(f) and d135(f), which are shown in FIG. 6A. Incidentally, the focus value f is acquired as a command value issued from the astigmatism adjustment unit 64 to the focal-position control unit 22. It should be noted that, as will be described later, the focus f is changed in two or more scanning directions in picture processing so as to improve precision.

(2) Subsequently, at the next step S52, the astigmatism & focus-correction-quantity-computation picture-processing unit 53 is driven to find center positions p0, p45, p90 and p135 of curves representing the degrees of directional sharpness at angles of 0, 45, 90 and 135 degrees, namely, d0(f), d45(f), d90(f) and d135(f) respectively, each as a function of focus f as shown in FIG. 6A.

(3) Then, at the following step S53, the astigmatism & focus-correction-quantity-computation picture-processing unit 53 is driven to find a focal-position shift (astigmatic difference)'s direction α and magnitude 67 as well as a focal offset z in a direction caused by the astigmatic difference from a sinusoidal relation shown in FIG. 6B for each of the center positions p0, p45, p90 and p135, and supply them to the overall control unit 26 to be stored in the storage unit 57. It should be noted that, at the step S53, it is not absolutely necessary to find the astigmatic difference's direction α and magnitude δ. Instead, only a vector (dx, dy) representing the astigmatic difference needs to be found. The magnitude δ of the astigmatic difference is represented by Eq. (1) below. The direction α of the astigmatic difference (or the direction of the focal-position shift) is expressed by Eq. (2) below. The focal offset z is represented by Eq. (3) below.

67 2=(p0−p90)²+(p45−p135)²=(dx)²+dy² (1)

α=(½)tan⁻¹((p45−p135)/(p0−p90))=(½)tan⁻¹((dy/dx)) (2)

z=(p0+p45+p90+p135)/4 (3)

It should be noted that a storage unit 54 is used for storing, among others, a program for finding the degrees of directional sharpness d0(f), d45(f), d90(f) and d135(f), a program for finding the center positions p0, p45, p90 and p135 from the degrees of directional sharpness d0(f), d45(f), d90(f) and d135(f) and a program for finding the astigmatic difference and the offset value. The astigmatism & focus-correction-quantity-computation picture-processing unit 53 is capable of executing these programs. The storage unit 54 can be a ROM or the like.

(4) There has been found in advance a relation between variations in astigmatism control values (stx, sty), which are characteristics of the astigmatism cor rector 60, and variations in astigmatic difference's direction a and magnitude d or variations in astigmatic-difference vector (dx, dy). The variations in astigmatic difference's direction a and magnitude d or variations in astigmatic-difference vector (dx, dy) are known as sensitivity. Thus, at the next step S54, the overall control unit 26 is capable of converting and splitting the astigmatic difference's direction a and magnitude d or the vector (dx, dy) into required astigmatism correction quantities (1, 2) (Δstx, Δsty) on the basis of this relation. Then, at the next step S55, the overall control unit 26 is capable of setting the astigmatism correction quantities (1, 2) (Δstx, Δsty) as well as a focal offset z and supplying them to the astigmatism adjustment unit 64. It should be noted that the astigmatism correction quantities (1, 2) (Δstx, Δsty) and the focal offset z can also be computed by the astigmatism & focus-correction-quantity-computation picture-processing unit 53 instead of the overall control unit 26. In this case, the astigmatism & focus-correction-quantity-computation picture-processing unit 53 receives characteristics of the astigmatism corrector 60 and the objective lens 18 from the overall control unit 26.

(5) The astigmatism adjustment unit 64 transmits the focal offset z received from the overall control unit 26 to the focal-position control unit 22, which uses the focal offset z to correct an objective-coil current flowing through the objective lens 18 or a focus correction coil current flowing through the focus correction coil 18a. The astigmatism adjustment unit 64 transmits the astigmatism correction quantities (Δstx, Δsty) received from the overall control unit 26 to an astigmatism correction circuit 61, which uses the astigmatism correction quantities (Δstx, Δsty) to correct an astigmatism correction coil current or an astigmatism correction static voltage. In this way, the correction and the adjustment of the astigmatism can be carried out at the same time.

(6) For small astigmatism, an auto-stigma operation is completed in one processing described above. For large astigmatism, however, the correction cannot be completed in one processing due to causes of aberration other than the astigmatism. Examples of such causes are high-order astigmatism and picture distortion. In this case, the processing goes back to step (1) to apply an auto stigma and repeat the loop till the astigmatism correction quantities (Δstx, Δsty) and the focal offset z are reduced to small values.

In accordance with the method described above, it is possible to implement simultaneous adjustment of astigmatism and a focus in a short period of time with little damage inflicted upon the sample 20 and the calibration target 62. In addition, by comparing directional sharpness of pictures of the same sample 20 or the same calibration target 62 while varying the focal distance, an astigmatic difference can be found. Thus, the simultaneous adjustment of astigmatism and a focus can be implemented independently of a pattern on the sample 20 or the calibration target 62, that is, a pattern for astigmatism and focus correction. The only condition imposed on the pattern on the sample 20 or the calibration target 62 is that the pattern shall include edge elements to the same degree in all directions.

In the embodiment described above, four types of directional sharpness at θ=0, 45, 90 and 135 degrees are used. It should be noted, however, that if the astigmatic difference's direction a and magnitude d are known, not all the four directions at θ=0, 45, 90 and 135 degrees need to be used. That is to say, only degrees of directional sharpness dθ(f) for at least 3 angles θ corresponding to three directions are required. In this case, for each θ, a center position pθ of the curve dθ(f) is found. Then, a sinusoidal waveform or a waveform close to the sinusoidal waveform is applied to pθ. The astigmatic difference's direction a and magnitude d can be found as the phase and the amplitude of the sinusoidal waveform respectively.

The following description explains a concrete embodiment implementing processing carried out by the astigmatism & focus-correction-quantity-computation picture-processing unit 53 to find directional sharpness of a particle picture.

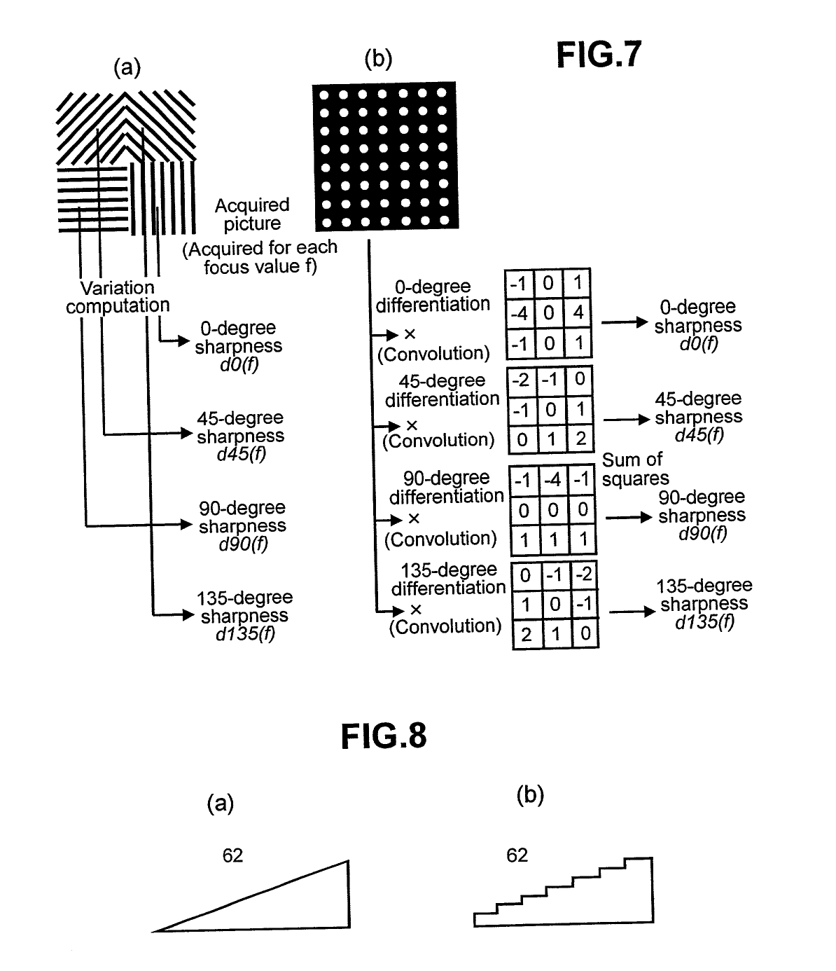

As a first embodiment, a particle picture is detected and observed by the particle detector 16. The particle picture is detected by radiating a charged-particle beam to a sample (target) 62 in a scanning operation. The target 62 is used specially for automatic correction of astigmatism. The sample 62 has a striped pattern with a stripe direction varying from area to area as shown in FIG. 7A. The directional sharpness dθ is found by measuring the amplitude of a particle picture in each area. The amplitude can be found by directly measuring an amplitude {=a maximum value of s (x, y)−a minimum value of s (x, y)} in each area or by measuring a variance of a concentration quantity (gradation quantity) of a particle picture in each area. The variation V is expressed by the following equation:

V=Σxy(s(x, y)−s mean)2/N

As an alternative, the amplitude can also be found by computing a sum of absolute values Σxy|t(x, y)| or a sum of squares Σxy (t(x, y))² where notation t (x, y) denotes a differential obtained as a result of 2-dimensional differentiation such as Laplacian differentiation of s (x, y), notation |t (x, y)| denotes the absolute value of the differential t (x, y) and notation (t(x, y))² denotes the square of the differential t(x, y). In this case, the result defines the directional sharpness dθ. The angular direction θ can be defined in any way. In the figure, an angular direction of 0 degrees is defined for a normal direction of the pattern coinciding with the horizontal direction. The angular direction ? is then defined in a clockwise manner with the angular direction of 0 degrees taken as a reference. Directions of the pattern are not limited to the four directions shown in the figure. That is to say, the directions of the pattern may be a combination of arbitrary angles that divide a 180-degree-area into about n equal parts, where n is any arbitrary integer equal to or greater than 3.

A second embodiment is provided for a pattern created on the sample 20 or the target 62 as shown in FIG. 7B. In this case, the directional sharpness dθ is found by carrying out a directional-differentiation process on a particle picture detected by the particle detector 16. The directional-differentiation process is carried out by convolution of a mask like one shown in the figure on the picture. Then, a sum of squares of values at all points on the picture of a differentiation is computed to be used as the directional sharpness dθ. The differentiation mask shown in the figure is a typical mask. Any mask other than the typical mask can be used as long as the other mask satisfies a condition for the differentiation. The condition requires that two pieces of data at any two positions symmetrical with each other with respect to a certain axis shall have signs opposite to each other and equal absolute values. For suppression of noises and improvement of direction selectability, there are conceived a variety of differentiation masks. In addition, it is necessary to select a type of filtering prior to computation of picture differentials and select a picture-shrinking technique appropriate for the picture. Furthermore, by carrying out the directional-differentiation process after rotating the picture, it is possible to perform the directional-differentiation process in any direction ? by using the simple 0-degree or 90-degree differentiation.

Moreover, in order to find the directional sharpness with a high degree of accuracy, the following technique can be adopted. As shown in FIG. 16, curves representing sharpness at angles 0, 90, 45 and 135 degrees have different properties due to the direction of the scanning line, the frequency response of the detector and characteristics of noises. Thus, in a technique of finding degrees of sharpness in four directions by a directional differentiation process carried out on a picture, there is raised a problem related to errors of astigmatism. To be more specific, for degrees of sharpness at 0 and 90 degrees, the bottom's height relative to the height of the peak is comparatively large. In the case of the 0-degree angle, in particular, the magnitudes of the noises are large, increasing an error generated in processing to find the center of a curve representing the sharpness. This is because, for the 90-degree direction, the differentiation process is carried out in a direction stretching over a plurality of scanning lines. Thus, the magnitudes of the noises increase due to an effect of variations in brightness, which are caused by differences in current magnitude among primary beams for scanning lines. As for the 0-degree direction, the differentiation process is carried out in the direction of the scanning line. Thus, the peak of the sharpness curve decreases by as large an amount as signal corruption caused by the frequency response of the detector. In the case of the 45 and 135-degree directions, on the other hand, if a differentiation filter with a low response is employed in both the horizontal and vertical directions, either effect is almost meaningless. As a result, a sharpness curve with a high peak and a low bottom is selected.

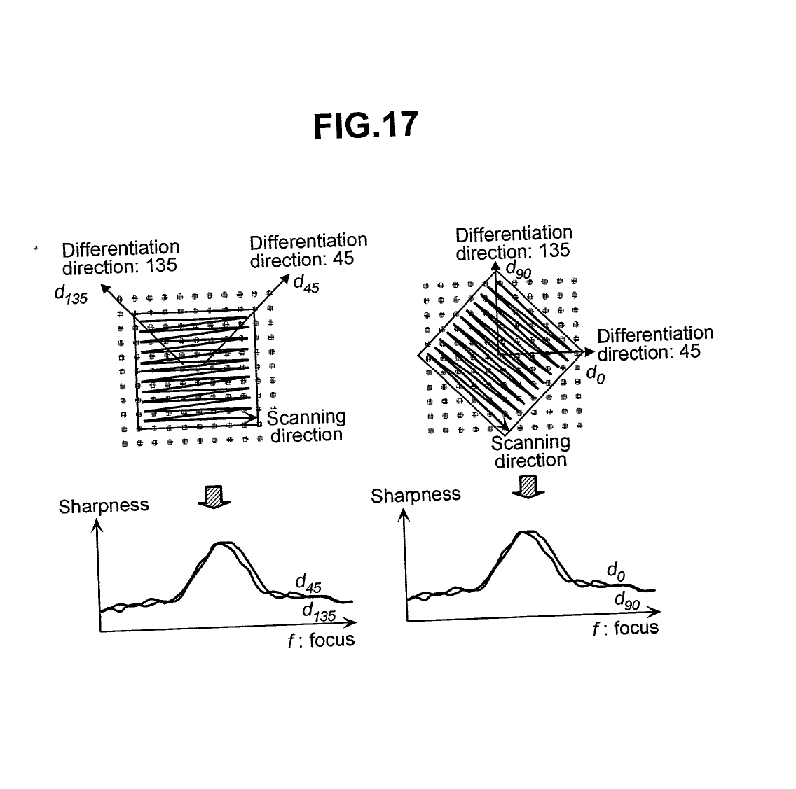

For the reason described above, the scanning direction is changed from the first focus sweep to the second focus sweep by about −45 degrees as shown in FIG. 17. Only degrees of sharpness at 45 and 135 degrees displaying an excellent property are computed by using their respective picture sets. In the second sweep, the picture has been rotated by 45 degrees. Thus, degrees of sharpness in the 0 and 90-degree directions, that is, d0 and d90, are computed. The scanning direction may also be rotated by 135 degrees instead of −45 degrees. As a matter of fact, the scanning direction may also be rotated by −135 degrees or 45 degrees. In this case, however, the differentiation direction of 45 degrees corresponds to the sharpness d90 whereas the differentiation direction of 135 degrees corresponds to the sharpness d0. It should be noted that, if the differentiation direction is shifted from 0 and 90 degrees, the differentiation process is not necessarily carried out in the ±45 and ±135-degree directions. For example, the differentiation process can be carried out in the 60 and 150-degree directions or the −150 and −60-degree directions on a picture, which is not rotated to produce directional sharpness that is proof against four types of noise. In this case, however, four degrees of sharpness {d15(f), d60(f), d105(f), d150(f)} are obtained by in accordance with the same equations described above by replacing all numbers representing angles in the equation with correct numbers for the angles of 15, 60, 105 and 150 degrees.

Thus, astigmatism can be measured with a high degree of accuracy and without being affected by noises even for a dim pattern. In addition, astigmatism can be measured and corrected even for a pattern darkened due to contamination of the sample or the like.

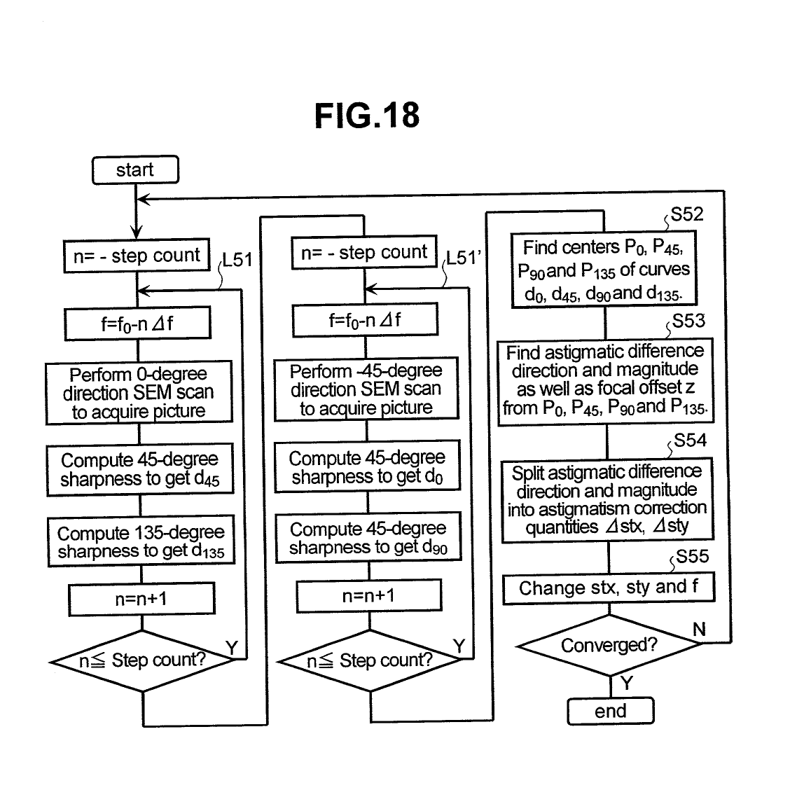

FIG. 18 is a flowchart representing processing to correct astigmatism for a case in which the directional sharpness is computed by adopting the method shown in FIG. 17.

(1) In a loop L51, while a charged-particle beam is being radiated to a pattern for correction of astigmatism and a focus in a scanning operation according to a command issued by the overall control unit 26 to the deflection control unit 47, the astigmatism adjustment unit 64 issues a command to the focal-position control unit 22 to make the following happen. While the focus f is being changed, the particle detector 16 acquires a plurality of pictures and stores them in the picture memory 52. The astigmatism & focus-correction-quantity-computation picture-processing unit 53 computes degrees of directional sharpness at angles of 45 and 135 degrees for the pictures, that is, the degrees of directional sharpness d45(f) and d135(f), which are shown in FIG. 17.

(2) Then, in the next loop L51′, while the charged-particle beam is being radiated to the pattern for correction of astigmatism and a focus in a scanning operation with the angle rotated from that of the loop 51 by −45 degrees in accordance with a command issued by the overall control unit 26 to the deflection control unit 47, the astigmatism adjustment unit 64 issues a command to the focal-position control unit 22 to make the following happen. While the focus f is being changed, the particle detector 16 acquires a plurality of pictures and stores them in the picture memory 52. The astigmatism & focus-correction-quantity-computation picture-processing unit 53 computes degrees of directional sharpness at angles of 45 and 135 degrees for the pictures, that is, the degrees of directional sharpness d0(f) and d90(f), which are shown in FIG. 17.

(3) Subsequently, at the next step S52, the astigmatism & focus-correction-quantity-computation picture-processing unit 53 is driven to find center positions p0, p45, p90 and p135 of curves representing the degrees of directional sharpness at the angles of 0, 45, 90 and 135 degrees, namely, d0(f), d45(f), d90(f) and d135(f) respectively, each as a function of focus f as shown in FIG. 6A.

(4) Then, at the following step S53, the astigmatism & focus-correction-quantity-computation picture-processing unit 53 is driven to find a focal-position shift (astigmatic difference)'s direction a and magnitude d as well as an focal offset z in a direction caused by the astigmatic difference from a sinusoidal relation shown in FIG. 6B for each of the center positions p0, p45, p90 and p135, and supply them to the overall control unit 26 to be stored in the storage unit 57. It should be noted that, at the step S53, it is not absolutely necessary to find the astigmatic difference's direction a and magnitude d. Instead, only a vector (dx, dy) representing the astigmatic difference needs to be found

(5) There has been found in advance a relation between variations in astigmatism control values (stx, sty), which are characteristics of the astigmatism corrector 60, and variations in astigmatic difference's direction a and magnitude d or variations in astigmatic-difference vector (dx, dy). The variations in astigmatic difference's direction a and magnitude d or variations in astigmatic-difference vector (dx, dy) are known as sensitivity. Thus, at step S54, the overall control unit 26 is capable of converting and splitting the astigmatic difference's direction a and magnitude d or vector (dx, dy) into required astigmatism correction quantities (1, 2) (Δstx, Δsty) on the basis of this relation. At step S55, the overall control unit 26 is capable of setting the astigmatism correction quantities (1, 2) (Δstx, Δsty) and a focal offset z and supplying them to the astigmatism adjustment unit 64.

(6) The astigmatism adjustment unit 64 transmits the focal offset z received from the overall control unit 26 to the focal-position control unit 22, which uses the focal offset z to correct an objective coil current flowing through the objective lens 18 or a focus correction coil current flowing through the focus correction coil 18a. The astigmatism adjustment unit 64 transmits the astigmatism correction quantities (Δstx, Δsty) received from the overall control unit 26 to the astigmatism correction circuit 61, which uses the astigmatism correction quantities (Δstx, Δsty) to correct an astigmatism correction coil current or an astigmatism correction static voltage. In this way, the correction and the adjustment of the astigmatism can be carried out at the same time.

(7) For small astigmatism, an auto-stigma operation is completed in one processing described above. For large astigmatism, however, the correction cannot be completed in one processing due to causes of aberration other than the astigmatism. Examples of such causes are high-order astigmatism and picture distortion. In this case, the processing goes back to step (1) to apply an auto stigma and repeat the loop till the astigmatism correction quantities (Δstx, Δsty) and the focal offset z are reduced to small values.

The following description explains an embodiment implementing a method based on another principle. The method is adopted to solve a phenomenon of differences in property among sharpness curves at 0, 90, 45 and 135 degrees as shown in FIG. 16. The differences are caused by effects of the direction of the scanning line, the frequency response of the detector and characteristics of noises. Brightness noises of the scanning line are generated at random. That is to say, brightness noises of the scanning line in an operation to scan a particle picture have no correlation with brightness noises generated in another operation to scan the particle picture under the same condition. In order to solve this problem, directional differentials are computed for each of two pictures. Then, by finding covariance values of pixels of the two differential pictures or their square roots, noise components can be eliminated. Thus, a square average of each of the differential pictures or its square root can be found. It should be noted that a covariance value can be computed as a value of the following expression: Σf (x, y) g (x, y)/N where notations f (x, y) and g (x, y) denote the two differential pictures respectively and notation N denotes the number of pixels in an area of covariance computation. By adopting this method, it is possible to suppress a phenomenon in which the bottom of a sharpness curve for 90 degrees is elevated by noises as shown in FIG. 16. It is also possible to improve stability and precision of the automatic aberration correction using a sample with a problem of a pattern sensitive to noises. A covariance value is computed for a pair of pictures, which are selected by two focus-scanning operations and have a common focal position f, as follows. Covariance values after the directional differentiation are found for differentiations in the 0, 45, 90 and 135 directions and used as the degrees of directional sharpness d0(f), d45(f), d90(f) and d135(f).

The following description explains a concrete embodiment of a method adopted by the astigmatism & focus-correction-quantity-computation picture-processing unit 53 to find the center position pθ of a directional-sharpness curve dθ(f), which is a function of focal position f. In accordance with a method to find the center position pθ of a directional-sharpness curve dθ(f), a quadratic function, a Gaussian function or the like is applied to values in close proximity to a focal position f corresponding to the peak of the directional-sharpness curve dθ(f). Thus, the center position pθ is found as the center position of the function. In accordance with a method to find the center position pθ of a directional-sharpness curve dθ(f), the center position pθ is found as the center of gravity of points representing values greater than a predetermined threshold. A proper method can be selected.

FIG. 11 is a diagram showing a graph representing a relation between the focus and the sharpness and serving as a means for explaining a method to find the center position pθ of a directional-sharpness curve dθ(f), wherein a Gaussian function or the like is applied to values in close proximity to a focal position f corresponding to the peak of the directional-sharpness curve dθ(f). To be more specific, a focal position f corresponding to the peak of the directional-sharpness curve dθ(f) is found and, then, a beetle-brow function such as a quadratic function or a Gaussian function is applied to N values in close proximity to the focal position f. For N=3, parameters can be determined so that the quadratic function or the Gaussian function passes all pieces of data. Thus, a center position of the directional-sharpness curve dθ(f) can be found by interpolation.

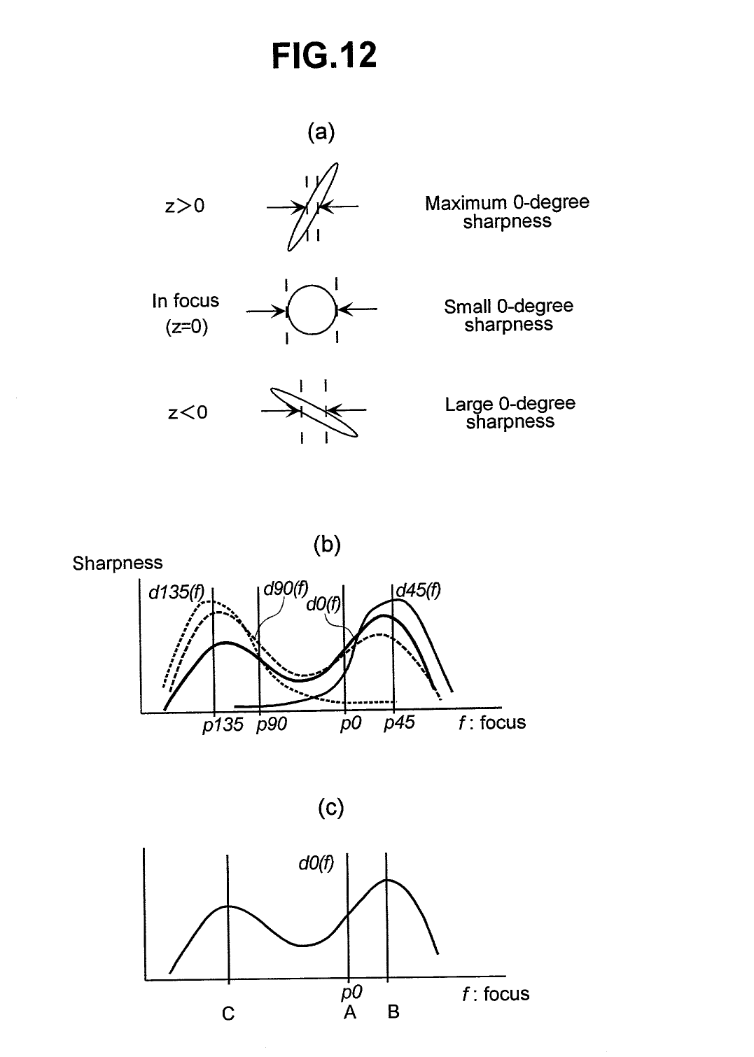

With the simple technique to find a position corresponding to a peak or the interpolation technique to find such a position, however, an error is generated particularly in the case of large astigmatism. This problem is explained by referring to FIG. 12. Consider sharpness in the 0-degree direction for a case in which astigmatism is generated in about ±45-degree directions as shown in FIG. 12A. In this case, when the spot cross section of the charged-particle line is in an in-focus state in the ±45-degree directions, the cross section of the spot for sharpness in the 0-degree direction is narrow. When the spot cross section of the charged-particle line is in an in-focus state in the 0-degree direction, on the other hand, the cross section of the spot for sharpness in the 0-degree direction is wide. The narrower the spot cross section, the higher the degree of sharpness. Thus, for large astigmatism, sharpness curves in a direction with no astigmatism generated reveal a trend of a double-peak property as is the case with the d0(f) and d90(f) curves shown in FIG. 12B. If the simple maximum-value method is adopted in this case, a one-sided position such as point B shown in FIG. 12C is incorrectly determined to be the center point of the d0(f) curve. In actuality, point B incorrectly determined to be the center point of the d0(f) curve is close to p45, which is a point corresponding to the peak of the d45(f) curve in this example.

In the example shown in FIG. 12, if the simple maximum-value method is adopted, point p0 corresponding to the peak of the d0(f) curve will be close to point p45 corresponding to the peak of the d45(f) curve while point p90 corresponding to the peak of the d90(f) curve will be close to point p135 corresponding to the peak of the d135(f) curve. In this case, components p45-p135 of the astigmatic difference in the ±45-degree directions have magnitudes at least twice the magnitudes, which are supposed to be. Thus, if those components are used for correction, the astigmatism in the directions will be inevitably over corrected, causing instability.

On the other hand, the method to search for a peak may determine point C shown in FIG. 12C to be the center of the d0(f) curve. In this case, the components of the astigmatism difference in the ±45-degree directions are not corrected. For this reason, it is necessary to find a middle point such as point A between points B and C shown in FIG. 12C as the center of the sharpness curve d0(f) in order to correctly find the magnitude of the astigmatic difference and the axial direction of the aberration as shown in FIG. 6.

In order to find such a middle point, in the present invention, the sizes of mountains B and C are taken into consideration so that the found middle point between points B and C truly represents the center of the directional sharpness. There are a variety of conceivable methods implemented by embodiments described below to find such a middle point. However, the methods to find such a middle point are not limited to the embodiments described below. In the case of a double-peak sharpness curve, any methods provided by the present invention can be adopted to find such a middle point by taking the sizes of the mountains into consideration.

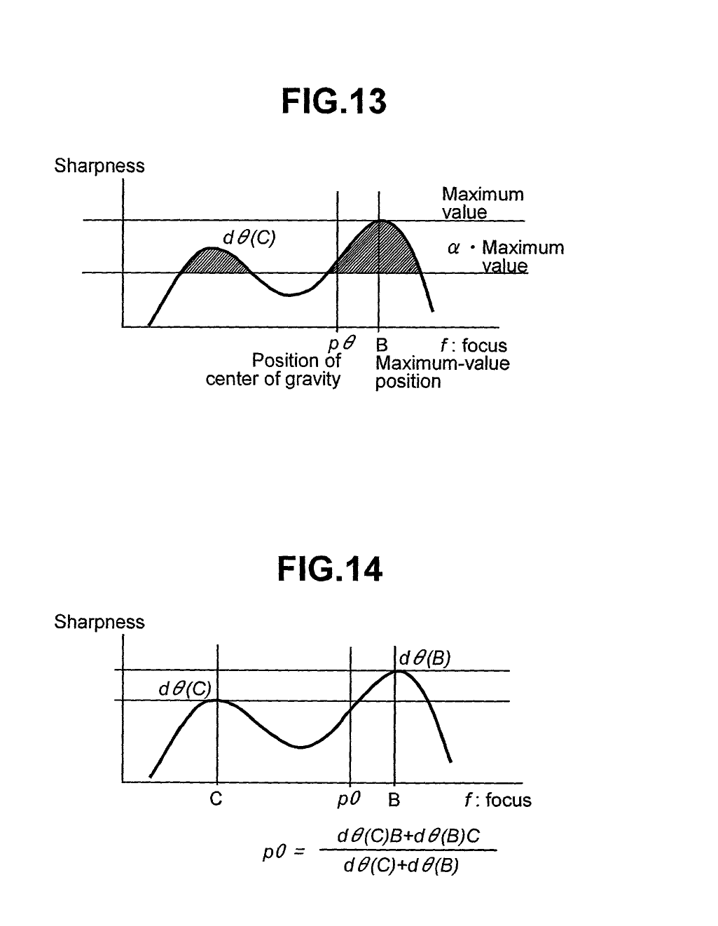

FIG. 13 is a diagram showing a graph representing a relation between the focus value and the sharpness and serving as a means for explaining a method of using the center of gravity of a directional-sharp curve as a central position of the curve. As described above, first of all, a maximum value is found. Then, a threshold value is found as a product of the maximum value and a coefficient a not greater than 1. The middle point of the directional sharpness is finally found as a center of gravity of hatched areas enclosed by the graph's portions representing sharpness greater than the threshold value and a horizontal line representing the threshold value. As described above, the graph represents variations in directional sharpness with variations in focal position. The middle point pθ of the directional sharpness is found as follows:

pθ=Σf*(dθ(f)−αMax Value)/pθ=Σd(dθ(f)−αMax Value)

FIG. 14 is a diagram showing a graph representing a relation between the focus value and the sharpness and serving as a means for explaining a method of finding a central position of a directional-sharp curve by computing a weighted average of maximum-value positions. If a plurality of peaks exist on a directional-sharpness curve, the positions of the peaks are first of all found. Then, a weight proportional to the height of a peak is found for each position and used for computing a weighted average representing the central point of the directional sharpness. Assume that notations B and C each denote the position of a maximum value. In this case, the middle point pθ of the directional sharpness is finally found as follows:

pθ=(dθ(C)*B+dθ(B)*C)/(dθ(C)dθ(B))

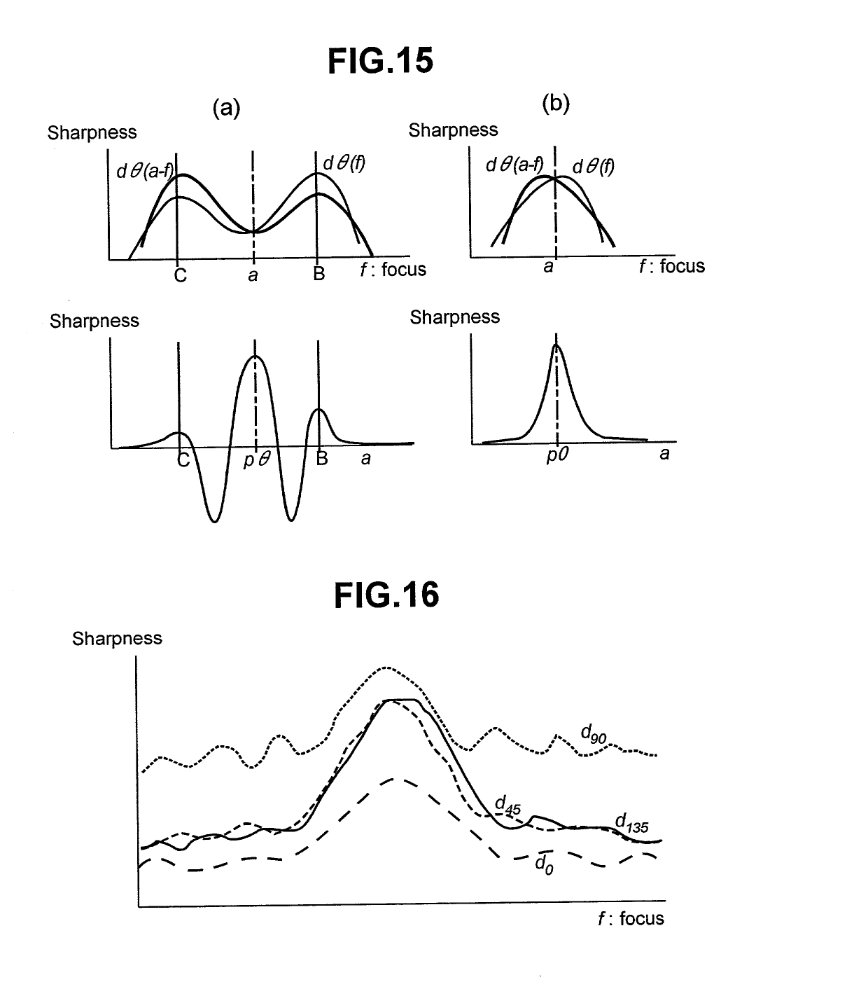

FIG. 15 includes graphs representing a relation between the focus value and the sharpness and serving as a means for explaining a method of finding a central position of a directional-sharp curve by adopting a symmetry-matching technique. In the figure, a curve dθ(f) represents variations in directional sharpness with variations in focal position. Consider a vertical line f=a passing through a position a as a symmetrical axis. The position a is selected so that the portion of a curve dθ(a-f) on the left side of the symmetrical axis becomes the most matching image of the portion of the curve dθ(f) on the right side of the symmetrical axis serving as an error. On the other hand, the portion of the curve dθ(a-f) on the right side of the symmetrical axis becomes the most matching image of the portion of the curve dθ(f) on the left side of the symmetrical axis. The curves on the lower side each represent variations in degree of matching with variations in position a. The position a at which the degree of matching reaches a maximum is taken as the in-focus position pθ. The degree of matching can be computed as a correlation quantity between the curves. In this case, at the in-focus position pθ, the correlation quantity reaches a maximum. The degree of matching can also be computed as a sum of squared differences between the curves. In this case, at the in-focus position pθ, the correlation quantity reaches a minimum. It is needless to say that the degree of matching can also be computed as any quantity that is generally used as an indicator of matching.

The following description explains a concrete embodiment implementing a technique adopted by the overall control unit 26 to compute an astigmatism correction quantity from an astigmatic difference received from the astigmatism & focus-correction-quantity-computation picture-processing unit 53. When the four directions of the in-focus positions p0, p45, p90 and p135 at 0, 45, 90 and 135 degrees are used, first of all, the astigmatism & focus-correction-quantity-computation picture-processing unit 53 computes an astigmatic-difference vector (dx, dy)=(p0-p90, p45-p135) and supplies the vector to the overall control unit 26. Then, the overall control unit 26 splits astigmatism correction quantities (Δstx, Δsty) on the basis of Eq. (4) given as follows:

Δstx=mxx*dx+mxy*dy

Δsty=myx*dx+myy*dy (4)

where notations mxx, mxy, myx and myy each denote a parameter of astigmatism correction quantity splitting, which are computed on the basis of characteristics of the astigmatism corrector 60. Typically, the parameters are stored in the storage unit 57. Thus, the astigmatism adjustment unit 64 supplies the astigmatism correction quantities obtained from the overall control unit 26 to the astigmatism correction circuit 61 so that the astigmatism correction circuit 61 changes the quantities by (βΔstx, βΔsty) where notation β denotes a correction quantity reduction coefficient. In turn, the astigmatism correction circuit 61 drives the astigmatism corrector 60 to change the astigmatism correction quantities by (βΔstx, βΔsty).

In addition, since the focal offset z obtained from the picture-processing circuit 53 is an average value of focal positions in different directions, the overall control unit 26 sets the focus correction quantity at (p0+p45+p90+p135)/4. Thus, the astigmatism adjustment unit 64 supplies the focus correction quantity obtained from the overall control unit 26 to typically the focal-position control unit 22, which then corrects the objective lens 18 by the focus correction quantity.

It should be noted that, as another embodiment, the astigmatism & focus-correction-quantity-computation picture-processing unit 53 first computes the astigmatic difference's magnitude δ=|(dx, dy)| and direction α=½ arctan (dy/dx), supplying the magnitude and the direction to the overall control unit 26. The overall control unit 26 may then convert the astigmatic difference's magnitude d and direction α into the astigmatism correction quantities (Δstx, Δsty).

In addition, when directional sharpness pθ in n directions is used where n is an integer of at least 3, the astigmatism & focus-correction-quantity-computation picture-processing unit 53 needs to apply a sinusoidal waveform to these pieces of data and then find the astigmatic difference's magnitude d and direction a as well as the focal offset z from the phase, the amplitude and the offset of the waveform.

Furthermore, if the astigmatism correction quantity is changed, the focal position may be affected by the change, being slightly shifted in some cases. Thus, in this case, the overall control unit 26 typically multiplies each of the astigmatism correction quantities (Δstx, Δsty) by a proper coefficient and adds the products to variations of the astigmatism correction quantities (Δstx, Δsty) to produce new astigmatism correction quantities.

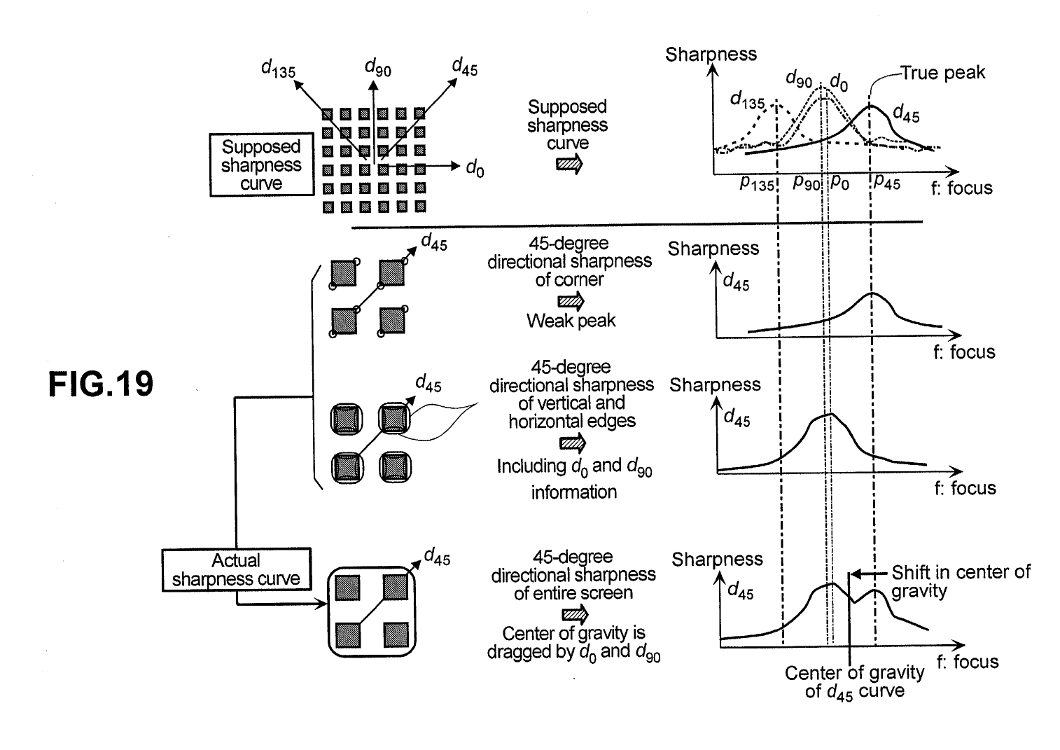

The following description explains an embodiment implementing a method to compute the astigmatism correction quantities more accurately, in a shorter period of time and with a higher degree of precision in comparison with the embodiment described above. With the method described above, there occurs a phenomenon wherein the position of the gravitational center of sharpness is dragged by sharpness in the adjacent direction. Consider a sharpness curve d45 in a 45-degree direction relative to, for example, a pattern like one shown in FIG. 19. As shown in the figure, the pattern includes more vertical and horizontal edges than inclined edges. Since edges oriented in an inclined direction exist at only corners of the pattern, the effects of the vertical and horizontal edges on the sharpness curve d45 are relatively strong, generating a peak not only at the supposed peak position, but also at peak positions of the sharpness curves d0 and d90. This phenomenon also holds true of the sharpness curve d135. For this reason, the component dx of an astigmatic-difference vector computed by adopting the technique of the center of gravity has a value smaller than the actual value to a certain degree. When a semiconductor is used as the sample 20, in general, the semiconductor pattern is a vertical and horizontal pattern. Thus, the phenomenon described above does not occur.

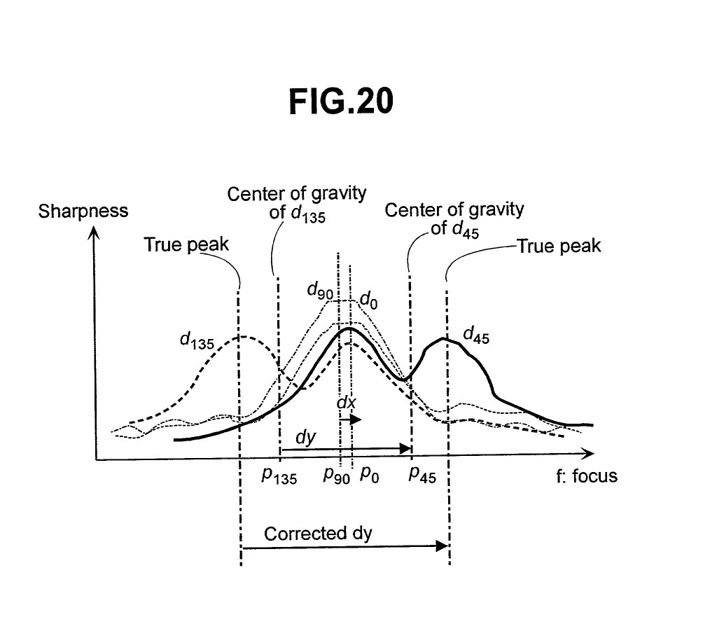

Thus, a corrected astigmatic-difference vector is used to find the astigmatism correction quantities (Δstx, Δsty). As shown in FIG. 20, the component dx of an astigmatic-difference vector is small in comparison with the component dy and the peaks d0 and d90 are high. In this case, the component dy of the astigmatic-difference vector is shifted in a direction toward a value smaller than an actual one. Thus, an equation usable for correcting it must be utilized. The following three kinds of correction equation are given as an example. In order to obtain the same effects, however, it is also possible to use other equations having similar functions to carry out the correction. With the first correction equation, the astigmatic-difference vector (dx, dy) is corrected in accordance with a relation between the magnitudes of the components dx and dy of the astigmatic-difference vector. To be more specific, the astigmatic-difference vector (dx, dy)=(p0−p90, p45−p135) by using (dx/dy)ˆ p where the notation ˆ denotes exponentiation.

(5)

(6)

Eqs. (5) and (6) are used for splitting the astigmatism correction quantities. Notations mxx, mxy, myx and myy each denote a parameter for splitting the astigmatism correction quantities. In the above equations, notation p denotes a parameter for correcting a phenomenon in which the position of the sharpness center of gravity is dragged by sharpness in the adjacent direction. The parameter p has a value in the range 0<p<1.

With the second correction equation, on the other hand, the astigmatic-difference vector (dx, dy) is corrected in accordance with the heights of the peaks of the directional-sharpness curves in addition to the relation between the magnitudes of the components dx and dy of the astigmatic-difference vector. Assume that the values pd0, pd45, pd90 and pd135 are used as the heights of the peaks of the sharpness curves d0, d45, d90 and d135 respectively and assume that px=pd0+pd90 whereas py=pd45+pd135. In this case, the following equations hold true:

(7)

(8)

Eqs. (7) and (8) are used for splitting the astigmatism correction quantities. Notations a, bp, bd, cp and cd each denote a correction parameter. The a parameter has a value in the range 1 to 2. A typical value of the parameter a is 1.8. The parameters bp and bd each have a value of 5 whereas the parameters cp and cd each have a value of about 0.5. That is to say, for px<py and dx>dy, the component dx is corrected by a factor not exceeding a times. For px>py and dx<dy, on the other hand, the component dy is corrected by a magnification factor not exceeding a times.

(9)

(10)

Eqs. (9) and (10) are used for splitting the astigmatism correction quantities. Notations a, bp, bd, cp and cd each denote a correction parameter. The a parameter has a value in the range 1 to 2. A typical value of the parameter a is 1.8. The parameters bp and bd each have a value of about 2 whereas the parameters cp and cd each have a value of about 4. That is to say, for px<py and dx>dy, the component dx is corrected by a factor not exceeding a times. For px>py and dx<dy, on the other hand, the component dy is corrected by a magnification factor not exceeding a times.

By using these equations, even if a sample pattern exhibits a one-sided property in the direction thereof, the one-sided property can be corrected so that the astigmatism correction quantities can be computed with a high degree of precision. As a result, the astigmatism can be corrected in a short period of time and with a high degree of precision.

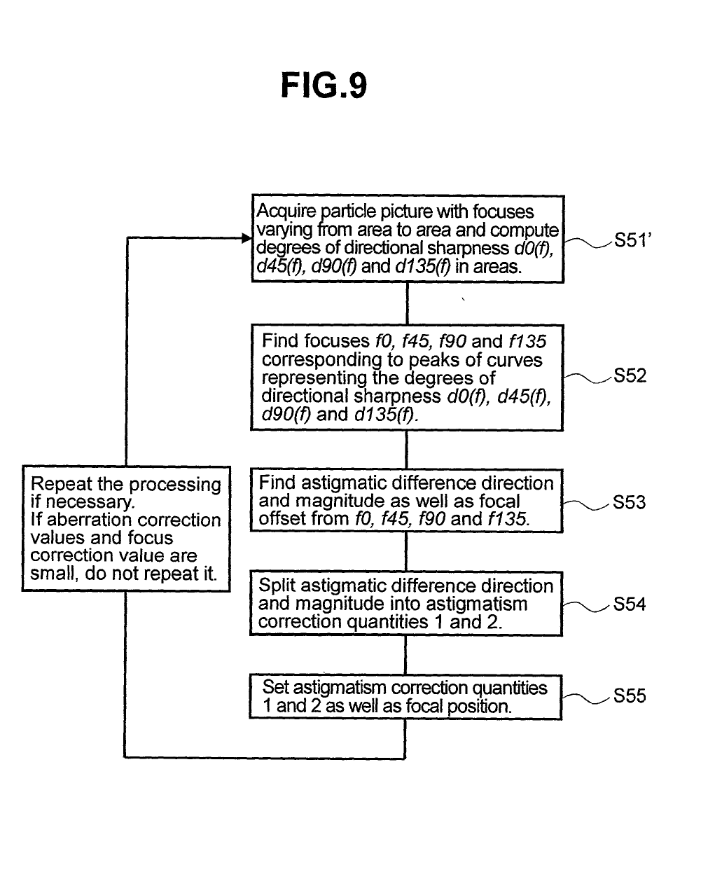

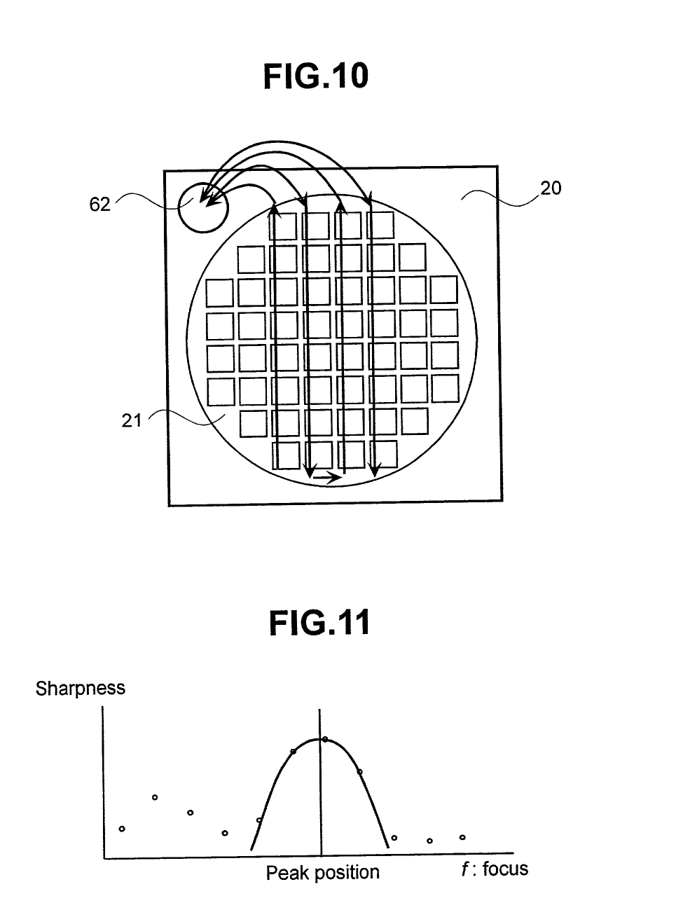

By referring to FIGS. 8 and 9, the following description explains the present invention's other embodiment implementing a technique for automatically correcting astigmatism and a focus in an even shorter period of time. In this embodiment, the surface of the calibration target 62 is inclined as shown in FIG. 8A. A proper pattern is created on the inclined surface to form a calibration target 62a. On the other hand, the calibration target 62 shown in FIG. 8B has a surface with a staircase shape. By the same token, a proper pattern is created on the staircase-shaped surface to form a calibration target 62b. The calibration target 62a or 62b is placed on the sample base 21 shown in FIGS. 1 and 10. By doing so, only one particle picture of the calibration target 62a or 62b created on the sample 20 needs to be taken in order to produce a picture with the focus f varying from area to area on the picture. If two pictures of it are taken by changing the scanning direction, it is possible to compute directional sharpness proof against noises as described earlier. It should be noted that a difference between the height of a reference point on the calibration target 62a and the height of the surface of the actual sample 20 as well as a difference between the height of a reference surface of the calibration target 62b and the height of the surface of the actual sample 20 have been measured in advance. As a typical method to measure such a difference, it is possible to apply automatic height correction to both the calibration target 62 and the sample 20 or use an optical height sensor to be described later.

That is to say, since the calibration target 62a shown in FIG. 8A or the calibration target 62b shown in FIG. 8B is used, it is possible to produce a picture with the focus f varying from area to area on the picture from different areas of only one particle picture. Thus, a flowchart shown in FIG. 9 is different from the flowchart shown in FIG. 5 in that, in place of the step S51 of the flowchart shown in FIG. 5, the flowchart shown in FIG. 9 includes a step S5′ to acquire a particle picture, which includes edge elements in at least 3 directions to the same degree and has a height (focus) f varying from area to area, and to compute the directional sharpness pθ(t) for each area. At the remaining steps S52 to S55, the astigmatism and focus correction quantities need to be found and used for adjusting the astigmatism and the focus in the same way as the corresponding steps of the flowchart shown in FIG. 5. In this way, by using only a picture, the astigmatism and the focus can be adjusted in a short period of time.

In addition, even if a calibration target 62 with a horizontal planar shape or the actual sample 20 is used, the same effects as the embodiment described above can be obtained. That is to say, if a particle picture is taken by varying the focal position at a high speed, a picture with a focus varying from area to area can be obtained in the same way as the embodiment described above. As a result, by using only a picture, the astigmatism and the focus can be adjusted in a short period of time.

The following description explains a relation between inspection or measurement of an object substrate and correction of astigmatism as well as correction of a focus. First of all, the object substrate (or the actual sample) 20 is mounted on the sample base 21. Then, the overall control unit 26 inputs and stores information on positions on the object substrate 20 to be scanned or measured. The information is acquired from an input means 59, which typically comprises a recording medium or a network. Thus, in an operation to scan or measure the object substrate 20, the overall control unit 26 issues a command to the XY stage 46 to control the XY stage 46 in order to take a predetermined position on the sample 20 to the visual field of the charged-particle optical system. Subsequently, a charged-particle beam is radiated to the predetermined position in a scanning operation, and a particle picture generated as a result of the scanning operation is detected by the particle detector 16. A signal representing the particle picture is then subjected to an A/D conversion to generate digital data to be stored in the picture memory 55. Then, the inspection & measurement picture-processing unit 56 carries out picture processing on the digital data stored in the picture memory 55 in an inspection or measurement operation. In the inspection or measurement operation, the astigmatism and the focus are corrected at each inspection or measurement position in accordance with the present invention so as to allow implementation of the inspection or the measurement based on a particle picture with aberration always corrected.

Assume that the height detection sensor 13 employed in the inspection & measurement apparatus is an optical height detection sensor, which has small bad effects such as charge-up, dirt and damage on the object substrate 20. With such sensor characteristics, a sample height detected by the optical height detection sensor 13 at each inspection or measurement position is fed back to the focal-position control unit 22 so that only a converged charged-particle beam for inspection or measurement is radiated to the object substrate (sample) 20 in a scanning operation without radiating a converged charged-particle beam for correcting astigmatism and a focus to the object substrate (sample) 20 in a scanning operation. As a result, bad effects such as charge-up, dirt and damage on the object substrate can be reduced to the minimum. In this case, automatic adjustment of astigmatism and a focus is carried out at another position on the sample 20 or at the calibration target 62 placed on the sample base 21 either in advance or periodically during an inspection or a measurement.

By the way, it possible to use a sample having an inclined or staircase-shaped surface as shown in FIG. 8, or a sample having a planar top surface as shown in FIG. 1 as the calibration target 62.

By carrying out automatic adjustment of astigmatism and a focus in accordance with the present invention as described above, it is possible to correct shifts in focal position and astigmatism, which normally occur with the lapse of time. In order to carry out the automatic adjustment of astigmatism and a focus in accordance with the present invention, however, it is necessary to adjust a detection offset of the optical height detection sensor 13 in advance. Differences (or variations) in height between inspection or measurement positions on the actual sample (object substrate) 20 are detected for use in correction of an in-focus state. Thus, a converged charged-particle beam with no astigmatism is radiated to the actual sample 20 in a scanning operation in an in-focus state only during an inspection or a measurement. Therefore, a particle picture can be detected with the effects such as charge-up, dirt and damage on the object substrate reduced to the minimum. As a result, the object substrate 20 can be inspected or measured with a high degree of precision.

In addition, when it is desired to calibrate not only an offset between the optical height detection sensor 13 and the focal-position control unit 22 but also a gain, a plurality of calibration targets 62 each having a known height are provided in advance. Such calibration targets 62 are used for carrying out both automatic correction of a focus and detection using the optical height detection sensor 13 so that the gain and, furthermore, linearity can also be calibrated as well. In addition, by carrying out both automatic correction of a focus and detection using the optical height detection sensor 13 while changing the height of the calibration target 62 or the sample 20 by using the Z-axis component of the XY stage 46, the gain and, furthermore, linearity can also be calibrated.

In addition, an inspection or a measurement can be carried out at a high speed by driving the beam deflector 15 to move a converged charged-particle beam in a scanning operation in a direction crossing (or, particularly, perpendicular to) the movement of the XY stage 46 while continuously moving the XY stage 46 in the horizontal direction a s shown in FIG. 10. In such an inspection or a measurement, the particle detector 16 continuously detects a particle picture. In order to carry out such an inspection or a measurement, the following control is executed.

A height detected by the optical height detection sensor 13 is always fed back to the focal-position control unit 22 and the deflection control unit 47. In addition, while a focal shift and deflection rotation are being corrected, a particle picture is detected continuously all the time. As a result, the entire surface of the actual sample 20 can be inspected or measured with a high degree of precision and a high degree of sensitivity. It should be noted that, in order to correct a focus, it is of course also possible to drive the Z-axis component of the XY stage 46 instead of driving the focal-position control unit 22 to provide the same effects as well. In the mean time, the radiation of the charged-particle beam is moved to the calibration target 62 periodically as shown in FIG. 10 to automatically correct the focus and the astigmatism. It is thus possible to inspect the sample 20 with a high degree of precision and a high degree of sensitivity by using a particle picture, which is obtained as a result of high-precision correction of astigmatism and a focus, over a long period of time.

The embodiments described above are applied to cases in which the charged-particle beam apparatus is applied to an inspection & measurement apparatus. It should be noted, however, that the present invention can also be applied to fabrication equipment and the like.

The present invention exhibits an effect that astigmatism and a focus can be automatically adjusted at a high speed and with a high degree of precision without inflicting damage upon a sample by using only a small number of particle pictures obtained by detection of a converged charged-particle beam radiated to the sample in a scanning operation.

In addition, the present invention also exhibits another effect that inspection or measurement can be carried out automatically with a high degree of stability and a high degree of precision while the quality of a particle picture detected over a long period of time is being maintained in operations to inspect defects such as impurities in a pattern or measure dimensions of the pattern on the basis of a particle picture detected by radiation of a converged charged-particle beam to an object substrate including the pattern in a scanning operation wherein the converged charged-particle beam has been subjected to high-speed and high-precision automatic adjustment of astigmatism and a focus without inflicting damage on the sample.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A charged-particle beam apparatus comprising:
a stage on which a sample is set;
a charged-particle optical system for converging a charged-particle beam generated by a charged-particle source;
a scanning means for scanning said sample by radiating said charged-particle beam converged by said charged-particle optical system to said sample;
a focus control means for controlling a focal position of said charged-particle beam converged by said charged-particle optical system;
an astigmatism adjustment means for adjusting astigmatism of said charged-particle beam converged by said charged-particle optical system;
a particle-picture detection means for detecting particle pictures, which are generated by said sample scanned by said scanning means by radiating said converged charged-particle beam to said sample and each have a plurality of focal positions, and for obtaining a 2-dimensional particle picture having a plurality of focal positions;
a picture-processing means for computing an astigmatic difference of said converged charged-particle beam on the basis of said 2-dimensional particle picture which has a plurality of focal positions and is obtained by said particle-picture detection means; and
a control system for adjusting and controlling said astigmatism of said converged charged-particle beam by feeding back an astigmatism correction quantity based on said converged charged-particle beam's astigmatic difference computed by said picture-processing means to said astigmatism adjustment means.

2. A charged-particle beam apparatus according to claim 1 wherein said particle-picture detection means carries out a focus scanning operation to obtain said 2-dimensional particle picture having a plurality of focal positions two times.

3. A charged-particle beam apparatus according to claim 1 wherein said picture-processing means further computes a focal offset based on said 2-dimensional particle picture having a plurality of focal positions.

4. A charged-particle beam apparatus according to claim 3 wherein said control system further feed backs a focus correction quantity based on said converged charged-particle beam's focal offset computed by said picture-processing means to said focus control means in order to adjust and control said converged charged-particle beam.

5. A charged-particle beam apparatus according to claim 1 wherein said control system carries out non-linear processing to find an astigmatism correction quantity based on said converged charged-particle beam's astigmatic difference computed by said picture-processing means.

6. A charged-particle beam apparatus according to claim 1 wherein said particle-picture detection means carries out a focus scanning operation to obtain said 2-dimensional particle picture having a plurality of focal positions two times by changing a picture direction by about 45 degrees, about 135 degrees, about −45 degrees or about −135 degrees.

7. A charged-particle beam apparatus according to claim 6 wherein said picture-processing means:
finds sharpness in a 45-degree direction and sharpness in a 135-degree direction of two types of 2-dimensional particle picture from each of said 2-dimensional particle pictures with different scanning angles and each with a plurality of focal positions, which pictures are obtained from said particle-picture detection means;
finds pieces of directional-sharpness data for said focal positions in four directions, namely, a 0-degree direction, a 45-degree direction, a 90-degree direction and a 135-degree direction, from collected results of a focus scan operation carried out two times;
finds in-focus positions in at least said four found pieces of directional-sharpness data; and
computes an astigmatic difference of said converged charged-particle beam from a relation among said in-focus positions for said four directions.

8. A charged-particle beam apparatus according to claim 1 wherein said particle-picture-detection means carries out a focus scan operation to obtain a 2-dimensional particle picture having a plurality of focus positions two times whereas said picture-processing means:
finds pieces of directional-sharpness data in four directions, namely, a 0-degree direction, a 45-degree direction, a 90-degree direction and a 135-degree direction, from focal positions corresponding to said first and second focus scan operations and covariance values of differential pictures in differentiation directions or square roots of said covariance values for said differential pictures in said four directions, namely, said 0-degree direction, said 45-degree direction, said 90-degree direction and said 135-degree direction, of 2-dimensional particle pictures from said 2-dimensional particle pictures, which each have a plurality of focal positions and are obtained from said particle-picture detection means;
finds in-focus positions in at least said found pieces of directional sharpness data in said four directions; and
computes an astigmatic difference and a focal offset of said converged charged-particle beam from a relation among said in-focus positions for said four directions.

9. A charged-particle beam apparatus according to claim 1 wherein said sample has a pattern created thereon to include edge elements in at least three directions.

10. A charged-particle beam apparatus according to claim 1 wherein said sample has at least three areas each including a sub-pattern having an edge element so that said sample has a pattern created thereon to include edge elements in at least three directions.

11. A charged-particle beam apparatus according to claim 1 wherein said particle-picture detection means controls said focus control means to detect a particle picture having a plurality of focal positions from said sample.

12. A charged-particle beam apparatus according to claim 1 wherein said particle-picture detection means detects a particle picture having a plurality of focal positions from a plurality of areas different from each other on said sample.

13. A charged-particle beam apparatus according to claim 1 wherein said sample is an inclined sample or a sample having a staircase-shaped surface.

14. A charged-particle beam apparatus according to claim 1 wherein, while said focus control means is changing a focal position for said sample at a high speed, said scanning means radiates said converged charged-particle beam to said sample in a scanning operation.

15. A charged-particle beam apparatus according to claim 1, further comprising a defect-inspection picture-processing means,
wherein said defect-inspection picture-processing means inspects said sample for a defect existing on said sample by using a particle picture;
said particle picture is obtained by said particle-picture detection means as a result of detection of particles, which are generated from said sample when said scanning means radiates said converged charged-particle beam to said sample in a scanning operation; and
said converged charged-particle beam has been subjected to adjustment and control of at least astigmatism thereof in said control system.

16. A charged-particle beam apparatus according to claim 1, further comprising:
a defect-inspection picture-processing means,
wherein said defect-inspection picture-processing means measures dimensions of a pattern existing on an object substrate serving as said sample by using a particle picture;
said particle picture is obtained by said particle-picture detection means as a result of detection of particles, which are generated from said object substrate when said scanning means radiates said converged charged-particle beam to said sample in a scanning operation; and
said converged charged-particle beam has been subjected to adjustment and control of at least astigmatism thereof in said control system.

17. A charged-particle beam apparatus according to claim 1, further comprising a height detection means for optically detecting a height on an object substrate serving as said sample,
wherein said focus control means is controlled on the basis of said optically detected height on said object substrate.

18. A method for automatically adjusting astigmatism of a charged-particle beam apparatus, comprising the steps of:
converging a charged-particle beam, which is generated by a charged-particle source, by using a charged-particle optical system;
radiating said converged charged-particle beam to a sample, on which a pattern has been created, in an operation to scan said sample;
obtaining a plurality of 2-dimensional particle pictures having focal positions different from each other by detecting particles, which are generated from said sample as a result of radiation of said converged charged-particle beam to said sample in an operation to scan said sample, synchronously with said operation to scan said sample while changing a focal position of said converged charged-particle beam;
computing an astigmatic difference of said converged charged-particle beam by using information contained in said 2-dimensional particle pictures having focal positions different from each other; and
controlling and adjusting said astigmatism of said converged charged-particle beam by feeding back an astigmatism correction quantity based on said computed astigmatic difference of said converged charged-particle beam to an astigmatism adjustment means.

19. A method for automatically adjusting astigmatism of a charged-particle beam apparatus according to claim 18, wherein an operation to obtain said 2-dimensional particle pictures having focal positions different from each other by changing a focal position of said converged charged-particle beam is carried out two times.

20. A method for automatically adjusting astigmatism of a charged-particle beam apparatus according to claim 18, wherein, at said step of computing an astigmatic difference, a focal offset of said converged charged-particle beam is further calculated.

21. A method for automatically adjusting astigmatism of a charged-particle beam apparatus according to claim 20, further comprising the step of adjusting and controlling a focus of said converged charged-particle beam by feeding back a focus correction quantity based on said calculated focal offset of said converged charged-particle beam to a focus control means.

22. A method for automatically adjusting astigmatism of a charged-particle beam apparatus according to claim 18, wherein said step of computing an astigmatic difference includes the sub-steps of:
finding degrees of directional sharpness in at least three directions from said 2-dimensional particle pictures having a plurality of focal positions for said focal positions;
finding in-focus positions at said found degrees of directional sharpness in at least said three directions; and
computing an astigmatic difference of said converged charged-particle beam from a relation among said found in-focus positions for at least said three directions.

23. A method for automatically adjusting astigmatism of a charged-particle beam apparatus according to claim 22, wherein, at said step of computing an astigmatic difference, said in-focus positions at said degrees of directional sharpness in at least said three directions are each found by execution of the sub-steps of:
finding a maximum value or a peak value for each of said degrees of directional sharpness; and
finding a true position by interpolation based on values in close proximity to said maximum value or said peak value.

24. A method for automatically adjusting astigmatism of a charged-particle beam apparatus according to claim 18, wherein, at said step of obtaining said 2-dimensional particle pictures, a focus scanning operation to obtain said 2-dimensional particle pictures is carried out 2 times by changing a picture direction by about 45 degrees, about 135 degrees, about −45 degrees or about −135 degrees.

25. A method for automatically adjusting astigmatism of a charged-particle beam apparatus according to claim 24, wherein said step of computing an astigmatic difference of said converged charged-particle beam includes the sub-steps of:
finding sharpness in a 45-degree direction a nd sharpness in a 135-degree direction of two types of 2-dimensional particle picture from each of said 2-dimensional particle pictures with different scanning angles and each with a plurality of focal positions, which pictures are obtained at said step of obtaining said 2-dimensional picture;
finding pieces of directional-sharpness data for said focal positions in four directions, namely, a 0-degree direction, a 45-degree direction, a 90-degree direction and a 135-degree direction, from collected results of a focus scan operation carried out two times;
finding in-focus positions in at least said found pieces of directional sharpness data in said four directions; and
computing an astigmatic difference and a focal offset of said converged charged-particle beam from a relation among said in-focus positions for said four directions.

26. A method for automatically adjusting astigmatism of a charged-particle beam apparatus according to claim 18, further comprising the step of inspecting an object substrate serving as said sample for a defect existing on said sample by using said 2-dimensional particle picture obtained as a result of detection of particles generated from said sample by radiation of said converged charged-particle beam to said sample in a scanning operation whereby said converged charged-particle beam has been subjected to adjustment and control of said astigmatism.

27. A method for automatically adjusting astigmatism of a charged-particle beam apparatus according to claim 18, further comprising the step of measuring dimensions of a pattern existing on an object substrate serving as said sample by using said 2-dimensional particle picture obtained as a result of detection of particles generated from said sample by radiation of said converged charged-particle beam to said sample in a scanning operation whereby said converged charged-particle beam has been subjected to adjustment and control of said astigmatism.

28. A method for automatically adjusting astigmatism of a charged-particle beam apparatus, said method comprising the steps of:
converging a charged-particle beam, which is generated by a charged-particle source, by using a charged-particle optical system;
radiating said converged charged-particle beam to a sample, on which a pattern has been created, in an operation to scan said sample;
obtaining a plurality of 2-dimensional particle pictures of said sample by detecting particles, which are generated from said sample as a result of radiation of said converged charged-particle beam to said sample in an operation to scan said sample, while sequentially changing a focal position of said converged charged-particle beam;
computing an astigmatic difference of said converged charged-particle beam by using information contained in said 2-dimensional particle pictures having focal positions different from each other;
finding an astigmatism correction quantity based on said computed astigmatic difference of said converged charged-particle beam; and
controlling and adjusting said astigmatism of said converged charged-particle beam by feeding back said found astigmatism correction quantity to an astigmatism adjustment means.

29. A method for automatically adjusting astigmatism of a charged-particle beam apparatus according to claim 28, wherein, at said step of obtaining a plurality of 2-dimensional particle pictures, an operation to obtain said 2-dimensional particle pictures having focal positions different from each other by sequentially changing a focal position of said converged charged-particle beam is carried out two times.

30. A method for automatically adjusting astigmatism of a charged-particle beam apparatus according to claim 28, further comprising the step of computing a focal offset by using information contained in said 2-dimensional particle pictures having focal positions different from each other.

31. A method for automatically adjusting astigmatism of a charged-particle beam apparatus according to claim 30, further comprising the step of adjusting and controlling a focus of said converged charged-particle beam on the basis of a defect calculated at said step of computing a focal offset.

32. A method for automatically adjusting astigmatism of a charged-particle beam apparatus according to claim 28, wherein, at said step of finding an astigmatism correction quantity based on a computed astigmatic difference of said converged charged-particle beam, said astigmatism correction quantity is found by carrying out non-linear processing.

33. A method for automatically adjusting astigmatism of a charged-particle beam apparatus according to claim 28, further comprising the steps of:
optically detecting a height of an object substrate serving as said sample; and
controlling a focus of said converged charged-particle beam on the basis of information on said detected height of said object substrate.

34. A method for automatically adjusting astigmatism of a charged-particle beam apparatus according to claim 28, further comprising the step of inspecting an object substrate serving as said sample for a defect existing on said sample by using said 2-dimensional particle picture obtained as a result of detection of particles generated from said sample by radiation of said converged charged-particle beam to said sample in a scanning operation whereby said converged charged-particle beam has been subjected to adjustment and control of said astigmatism.

35. A method for automatically adjusting astigmatism of a charged-particle beam apparatus according to claim 28, further comprising the step of measuring dimensions of a pattern existing on an object substrate serving as said sample by using said 2-dimensional particle picture obtained as a result of detection of particles generated from said sample by radiation of said converged charged-particle beam to said sample in a scanning operation whereby said converged charged-particle beam has been subjected to adjustment and control of said astigmatism.
